(19) United States
(12) Patent Application Publication
(10) Pub. No.: US 2026/0353834 A1
(43) Pub. Date: Nov. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chia-Yu LI, Tainan City (TW); Sheng-Chan LI, Tainan City (TW); Sheng-Chau CHEN, Tainan City (TW)

(21) Appl. No.: 19/195,853

(22) Filed: May 1, 2025

(51) Int. Cl. H10F 39/00

(52) U.S. Cl. CPC H10F 39/807; H10F 39/011; H10F 39/811

(57) ABSTRACT

An isolation structure in a pixel sensor array of an image sensor device is manufactured to include a liner. The liner may be formed as a passivation layer in a recess in which the isolation structure is to be formed. The material of the liner includes a high concentration of hydrogen (H). A treatment operation may be performed to cause electrons replace the hydrogen in the material of the liner. This results in the material of the liner having a net electronegativity. The electronegativity of the material of the liner reduces the likelihood of and/or the amount of charge buildup around the isolation structure, which increases the sensitivity of the pixel sensors of the pixel sensor array.

### BACKGROUND

Complementary metal oxide semiconductor (CMOS) image sensors utilize light-sensitive CMOS circuitry to convert light energy (e.g., photons) into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A-2C are diagrams of an example of an image sensor device described herein.

FIG. 3 is a diagram of an example of hydrogen concentration in a sensor device described herein.

FIGS. 4A-4E are diagrams of an example implementation of forming a processing device (or a portion thereof) described herein.

FIGS. 5A-5F are diagrams of an example implementation of forming a sensor device (or a portion thereof) described herein.

FIGS. 6A and 6B are diagrams of an example implementation of forming an image sensor device (or a portion thereof) described herein.

FIGS. 7A-7I are diagrams of an example implementation of forming a pixel sensor array of a sensor die (or a portion thereof) described herein.

FIG. 8 is a diagram of an example implementation of negatively charging a material of a liner layer of an isolation structure described herein.

FIG. 9 is a diagram of an example implementation of negatively charging a material of a liner layer of an isolation structure described herein.

FIG. 10 is a diagram of an example semiconductor processing tool described herein.

FIG. 11 is a diagram of an example implementation of a pixel sensor that may be included in a sensor device of an image sensor device described herein.

FIGS. 12A-12G are diagrams of an example implementation of forming a pixel sensor array of a sensor die (or a portion thereof) described herein.

FIG. 13 is a flowchart of an example process associated with forming a semiconductor device described herein.

FIG. 14 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Optical crosstalk may occur between adjacent pixel regions in a pixel sensor array. Optical crosstalk is a pixel sensor array performance issue, whereby incident light passes through a pixel sensor at a non-orthogonal angle and is at least partially absorbed by a photodiode of an adjacent pixel sensor. Optical crosstalk in a pixel sensor array of an image sensor device may degrade the spatial resolution of the image sensor, may reduce overall sensitivity of the image sensor device, may cause color mixing between pixel sensors of the image sensor device, may increase dark current levels of the image sensor device, may reduce optical responsivity of the image sensor device, may reduce white pixel performance, and/or may lead to image noise after color correction.

In some cases, a pixel sensor array of an image sensor device may include an isolation structure (e.g., deep trench isolation (DTI) structure). The isolation structure includes a plurality of interconnect segments that form an isolation grid that laterally surrounds the pixel sensors in the pixel sensor array. The isolation structure increases confinement of incident light to individual pixel sensors, which reduces optical crosstalk between the pixel sensors.

The process for forming an isolation structure includes etching a substrate layer of the image sensor device to form a plurality of interconnected trenches that resemble the shape and layout of the segments of the isolation structure. Various liners and/or layers may be deposited in the trenches to form the isolation structure. Etching of the substrate layer to form the trenches may result in damage to the substrate layer in the form of dangling bonds (e.g., silicon (Si) dangling bonds). These dangling bonds in the substrate layer can function as charge trapping sites in the substrate layer, which may result in a buildup of residual charge in the photodiodes of the pixel sensors of the pixel sensor array. The buildup of residual charge may decrease the optical sensitivity of the pixel sensors in that the buildup of residual charge raises the signal floor of the pixel sensors, thereby decreasing the difference between the lowest signal reading and the highest signal reading for the pixel sensors.

In some implementations described herein, an isolation structure in a pixel sensor array of an image sensor device is manufactured to include a liner that passivates the dangling bonds in a substrate layer of the image sensor that were formed during etching of the substrate layer to form the trenches in which the segments of the isolation structure were formed. As described herein, a liner may be formed as a passivation layer in a recess in which an isolation structure is to be formed.

The material of the liner includes a high concentration of hydrogen (H). The high hydrogen concentration may be achieved through in-situ doping and/or by another technique. The hydrogen in the material of the liner bonds to silicon (Si) in the material of the liner to form silicon-hydrogen (Si—H) bonds. A post-deposition treatment operation may be performed to break the silicon-hydrogen bonds in the material of the liner layer to cause the hydrogen to migrate to the dangling bonds in the substrate layer, which passivates the dangling bonds. Electrons replace the hydrogen in the material of the liner, becoming trapped at bonding sites previously occupied by the hydrogen in the material of the liner. This results in the material of the liner having a net electronegativity.

The electronegativity of the material of the liner, and/or the passivation of the dangling bonds of the substrate layer, reduces the likelihood of and/or the amount of charge buildup around the isolation structure, which increases the sensitivity of the pixel sensors of the pixel sensor array. The increased sensitivity of the pixel sensors may increase the responsiveness of the pixel sensors (which may increase low-light performance) and/or may increase the dynamic range of the pixel sensors, among other examples.

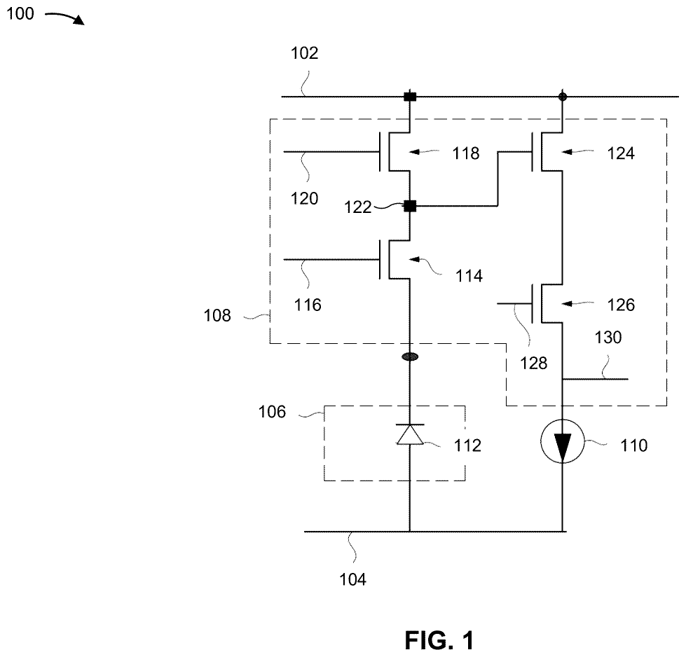

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor. The pixel sensor 100 may be electrically connected to a supply voltage (V_{dd}) 102 and an electrical ground 104.

The pixel sensor 100 includes a sensing region 106 that may be configured to sense and/or accumulate incident light (e.g., light directed toward the pixel sensor 100). The pixel sensor 100 also includes a control circuitry region 108. The control circuitry region 108 is electrically connected with the sensing region 106 and is configured to receive a photocurrent 110 that is generated by the sensing region 106. Moreover, the control circuitry region 108 is configured to transfer the photocurrent 110 from the sensing region 106 to downstream circuits such as amplifiers or analog-to-digital (AD) converters, among other examples.

The sensing region 106 includes a photodiode 112. The photodiode 112 may absorb and accumulate photons of the incident light, and may generate the photocurrent 110 based on absorbed photons. The magnitude of the photocurrent 110 is based on the amount of light collected in the photodiode 112. Thus, the accumulation of photons in the photodiode 112 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 112 is electrically connected with a source of a transfer gate 114 in the control circuitry region 108. The transfer gate 114 is configured to control the transfer of the photocurrent 110 from the photodiode 112. The photocurrent 110 is provided from the source of the transfer gate 114 to a drain of the transfer gate 114 based on selectively switching a gate of the transfer gate 114. The gate of the transfer gate 114 may be selectively switched by applying a transfer voltage (Vₜₓ) 116 to the transfer gate 114. In some implementations, the transfer voltage 116 being applied to the transfer gate 114 causes a conductive channel to form between the source and the drain of the transfer gate 114, which enables the photocurrent 110 to traverse along the conductive channel from the source to the drain. In some implementations, the transfer voltage 116 being removed from the transfer gate 114 (or the absence of the transfer voltage 116) causes the conductive channel to be removed such that the photocurrent 110 cannot pass from the source to the drain.

The control circuitry region 108 further includes a reset gate 118. The reset gate 118 is electrically connected to the supply voltage 102. The reset gate 118 may be controlled by a reset voltage (Vᵣₛₜ) 120. The transfer gate 114 and the reset gate 118 may be electrically coupled with a floating diffusion node 122. The reset voltage 120 may be applied to the reset gate 118 to pull the drain of the transfer gate 114 to a high voltage (e.g., to the supply voltage 102) to “reset” the floating diffusion node 122 (e.g., by draining any residual charge in the floating diffusion node 122) prior to activation of the transfer gate 114 to transfer the photocurrent 110 from the photodiode 112 to the floating diffusion node 122.

The photocurrent 110 may be used to apply a floating diffusion voltage (V_{fd}) to a source follower gate 124 of the control circuitry region 108. This permits the photocurrent 110 to be observed without removing or discharging the photocurrent 110 from the floating diffusion node 122. The reset gate 118 may instead be used to remove or discharge the photocurrent 110 from the floating diffusion node 122.

The source follower gate 124 functions as a high impedance amplifier for the pixel sensor 100. The source follower gate 124 provides a voltage to current conversion of the floating diffusion voltage. The output of the source follower gate 124 is electrically connected with a row select gate 126, which is configured to control the flow of the photocurrent 110 to external circuitry. The row select gate 126 is controlled by selectively applying a select voltage (V_{di}) 128 to the gate of the row select gate 126. This permits the photocurrent 110 to flow to an output 130 of the pixel sensor 100.

As indicated above, FIG. 1 is provided as an example. Other examples may differ from what is described with regard to FIG. 1.

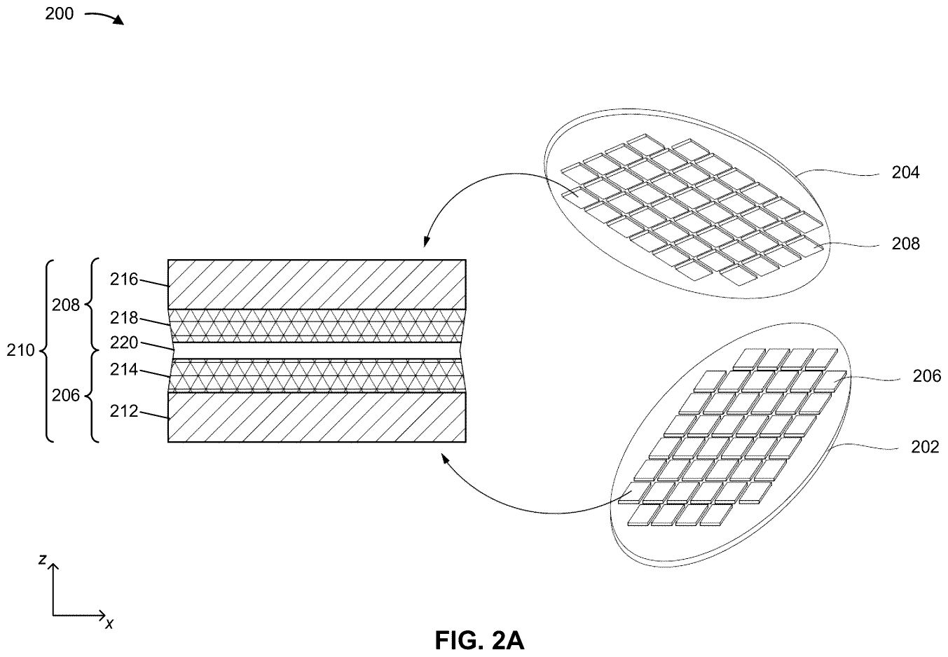

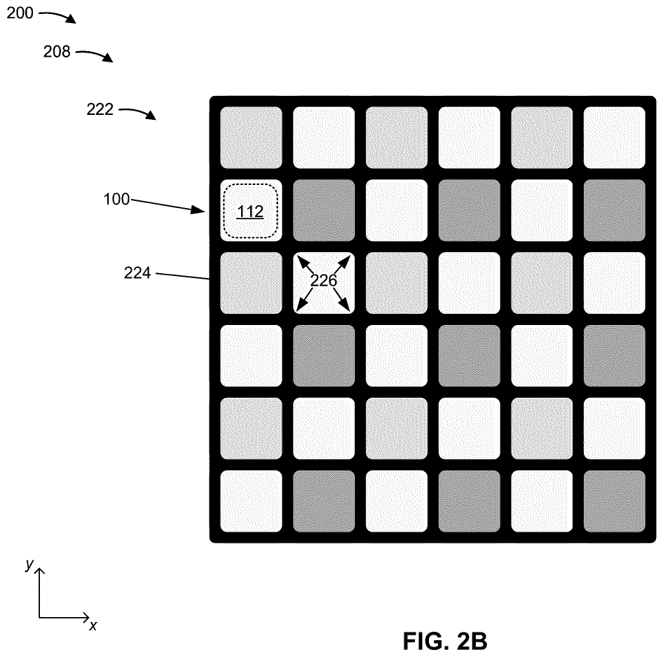

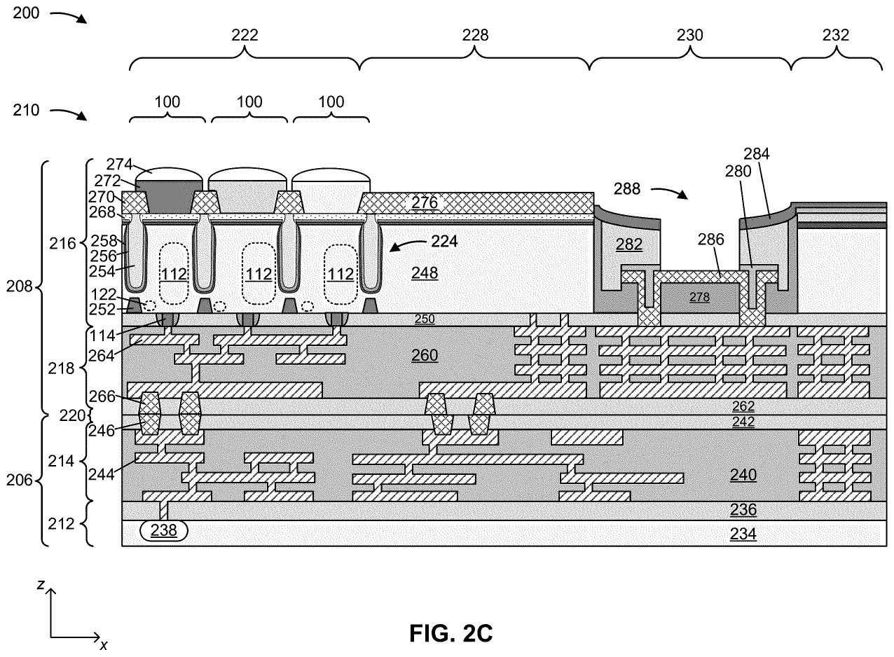

FIGS. 2A-2C are diagrams of an example 200 of an image sensor device described herein. As shown in FIG. 2A, an image sensor device may be formed by bonding a processing wafer 202 and a sensor wafer 204. For example, a bonding tool may be used to perform a bonding operation to bond the processing wafer 202 and the sensor wafer 204 using a metal-to-metal bonding technique, a dielectric-to-dielectric bonding technique, and/or another bonding technique. In the bonding operation, processing devices 206 on the processing wafer 202 are bonded with associated sensor devices 208 on the sensor wafer 204 to image sensor devices 210. The image sensor devices 210 are then diced and packaged. Other processing steps may be performed to form the image sensor devices 210.

Each image sensor device 210 includes a processing device 206 and a sensor device 208. The processing device 206 and the sensor device 208 may be stacked or vertically arranged in the image sensor device 210. Thus, an image sensor device 210 may be a three-dimensional (3D) complementary metal-oxide-semiconductor (CMOS) image sensor (3DCIS) device. The sensor devices 208 may be sensor dies or semiconductor dies that are manufactured on the sensor wafer 204 to include a pixel sensor array that includes a plurality of pixel sensors 100, or portions of a plurality of pixel sensors 100. In particular, the pixel sensor array of a sensor device 208 includes at least the sensing regions 106 (and thus, the photodiodes 112) of the pixel sensors 100. Accordingly, the sensor device 208 primarily is configured to sense photons of incident light and convert the photons to a photocurrent 110.

The processing device 206 may be processing dies (e.g., application-specific integrated circuit (ASIC) dies, system-on-chip (SOC) dies) or other semiconductor dies that are manufactured on the processing wafer 202 to include circuitry that is configured to measure, manipulate, and/or otherwise use the photocurrent 110. Moreover, a processing device 206 includes at least a subset of the transistors of the control circuitry regions 108 of the pixel sensors 100. For example, a processing device 206 may include the row select gates 126 of the pixel sensors 100, the source follower gates 124 of the pixel sensor, and/or a combination thereof. This provides increased area on the sensor device 208 for the photodiodes 112, which enables the size of the photodiodes 112 to be increased to increase the sensitivity and/or overall performance of the light sensing performance of the pixel sensor, and/or enables the size of the pixel sensors 100 to be decreased while maintaining the same size for the photodiodes 112.

As further shown in FIG. 2A, the processing device 206 may include a device layer 212 and an interconnect layer 214. The device layer 212 may include the devices (e.g., transistors) of the processing device 206, and the interconnect layer 214 may include interconnects that enable signals and/or power to be provided to and/or from the devices in the device layer 212. The sensor device 208 may also include a device layer 216 and an interconnect layer 218. The device layer 216 may include portions of the pixel sensors 100, including the photodiodes 112, the transfer gates 114, and the floating diffusion nodes 122, among other examples. The interconnect layer 218 may include interconnects that enable signals and/or power to be provided to and/or from the device layer 216.

The processing device 206 and the sensor device 208 may be bonded at a bonding interface 220, which may be included between the interconnect layers 214 and 218, and/or may be included in a portion of the interconnect layers 214 and/or 218. The bonding interface 220 may include bonding pads, bonding vias, bonding dielectric layers, and/or other bonding structures.

FIG. 2B is a top-down view of an example pixel sensor array 222 included on a sensor device 208. The pixel sensor array 222 may be included on a sensor device 208 of an image sensor device 210. As shown in FIG. 2B, the pixel sensor array 222 may include a plurality of pixel sensors 100 (or portions of the plurality of plurality of pixel sensors 100). For example, the pixel sensor array 222 may include the photodiodes 112 of the pixel sensors 100. As further shown in FIG. 2B, the pixel sensors 100 may be arranged in a grid. In some implementations, the pixel sensors 100 are square-shaped (as shown in the example in FIG. 2B). In some implementations, the pixel sensors 100 include other shapes such as rectangle shapes, circle shapes, octagon shapes, diamond shapes, and/or other shapes.

In some implementations, the size of the pixel sensors 100 (e.g., the width or the diameter) of the pixel sensors 100 is approximately 1 micron. In some implementations, the size of the pixel sensors 100 (e.g., the width or the diameter) of the pixel sensors 100 is less than approximately 1 micron. For example, a width of one or more of the pixel sensors 100 may be included in a range of approximately 0.6 microns to approximately 0.7 microns. In these examples, the pixel sensors 100 may be referred to as sub-micron pixel sensors. Sub-micron pixel sensors may decrease the pixel sensor pitch (e.g., the distance between adjacent pixel sensors) in the pixel sensor array 222, which may enable increased pixel sensor density in the pixel sensor array 222 (which can increase the performance of the pixel sensor array 222). However, other values for the range of the size of the pixel sensors 100 are within the scope of the present disclosure.

Each pixel sensor 100 may be configured to sense a particular wavelength range of incident light associated with a particular color component of the incident light. For example, a pixel sensor 100 may be configured to sense a wavelength range associated with a red component of incident light, and may therefore be referred to as a red pixel sensor. As another example, a pixel sensor 100 may be configured to sense a wavelength range associated with a blue component of incident light, and may therefore be referred to as a blue pixel sensor. As another example, a pixel sensor 100 may be configured to sense a wavelength range associated with a green component of incident light, and may therefore be referred to as a green pixel sensor. In some implementations, a plurality of pixel sensors 100 are configured to sense a wavelength range associated with a near infrared (NIR) component of incident light, and may therefore be referred to as NIR pixel sensors. The NIR pixel sensors may be included in the pixel sensor array 222 to improve low-light performance of the image sensor device 210 and/or to enable night-vision functionality to be realized for the image sensor device 210.

As further shown in FIG. 2B, the pixel sensors 100 may be electrically and optically isolated by an isolation structure 224 included in the pixel sensor array 222. The isolation structure 224 may include a plurality of interconnected and intersecting segments that extend into a substrate layer of the sensor device 208 and laterally surround the photodiodes 112 of the pixel sensors 100. The segments of the isolation structure 224 may be formed by etching the substrate layer to form a plurality of trenches that are filled with one or more types of materials, such as a dielectric material, a metal material, and/or another type of material. The trenches may be formed around the perimeters of the pixel sensors 100 such that the isolation structure 224 forms an isolation grid that surrounds the photodiodes 112 of the pixel sensors 100, as shown in FIG. 2B. The isolation structure 224 may include a deep trench isolation (DTI) structure or another type of structure that extends to a depth in the substrate layer at least partially along the photodiodes 112.

As further shown in the top view in FIG. 2B, the isolation structure 224 may have rounded corners 226 at locations where two or more segments of the isolation structure 224 intersect. The corners 226 may be rounded because of etch loading at the intersection locations of the trenches formed in the semiconductor layer. Etch loading may occur because of a greater amount of etchant flowing into the intersection locations than along the segments of the trenches, resulting in a greater etch rate in the intersection locations than in the segments of the trenches.

FIG. 2C illustrates a cross-section view of an image sensor device 210. As shown in FIG. 2C, a processing device 206 and a sensor device 208 may be bonded at a bonding interface 220 such that the processing device 206 and the sensor device 208 are stacked or vertically arranged in a z-direction in the image sensor device 210. As further shown in FIG. 2C, the image sensor device 210 includes the pixel sensor array 222 (e.g., including the pixel sensors 100), a black level correction (BLC) region 228 adjacent to (e.g., horizontally adjacent to) the pixel sensor array 222, a bonding pad region 230 adjacent to (e.g., horizontally adjacent to) the BLC region 228, and a seal ring region 232 adjacent to (e.g., horizontally adjacent to) the bonding pad region 230, among other examples. In a top view of the image sensor device 210, the BLC region 228, the bonding pad region 230, and/or the seal ring region 232 may laterally surround the pixel sensor array 222 and may be referred to as the periphery of the pixel sensor array 222.

As further shown in FIG. 2C, the image sensor device 210 includes a plurality of layers, such as the device layer 212 and the interconnect layer 214 of the processing device 206, and the device layer 216 and the interconnect layer 218 of the sensor device 208. The device layer 212 of the processing device 206 includes a semiconductor layer 234 and a dielectric layer 236 above the semiconductor layer 234. The semiconductor layer 234 may correspond to a portion of a substrate on which the processing device 206 was formed, and may include silicon (Si) (e.g., a silicon substrate), a material including silicon, a III-V compound semiconductor material such as gallium arsenide (GaAs), or another type of semiconductor material. The dielectric layer 236 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

Integrated circuit devices 238 may be included in and/or on the semiconductor layer 234 of the device layer 212. The integrated circuit devices 238 may include one or more ASIC devices, one or more SOC devices, one or more transistors, and/or one or more other components configured to measure the magnitude of a photocurrent 110 generated by the pixel sensors 100 to determine light intensity of incident light and/or to generate images and/or video (e.g., digital images, digital video).

The interconnect layer 214 of the processing device 206 may include a dielectric layer 240, a bonding layer 242, a plurality of interconnect structures 244 in the dielectric layer 240, and a plurality of bonding structures 246 in the bonding layer 242. The dielectric layer 240 may include one or more interlayer dielectric (ILD) layers, one or more intermetal dielectric (IMD) layers, and/or one or more etch stop layers (ESLs), among other examples. The dielectric layer 240 and the bonding layer 242 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 244 may each include conductive lines, trenches, vias, interconnects, metallization layers, and/or other types of electrically conductive structures that electrically connect the integrated circuit devices 238 to one or more other regions of the processing device 206 and/or to one or more regions of the sensor device 208, among other examples. The bonding structures 246 may each include bonding pads, bonding vias, and/or other types of bonding structures. The interconnect structures 244 and the bonding structures 246 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

The device layer 216 of the sensor device 208 includes a semiconductor layer 248 and a dielectric layer 250 below the semiconductor layer 248. The semiconductor layer 248 may correspond to at least a portion of a substrate (or substrate layer) on which the sensor device 208 was formed, and may include silicon (Si) (e.g., a silicon substrate), a silicon layer or another type of semiconductor layer, a material including silicon, a III-V compound semiconductor material such as gallium arsenide (GaAs), and/or or another type of semiconductor material. In some implementations, the semiconductor layer 248 is a layer of a silicon-on-insulator (SOI) substrate on which the sensor device 208 was formed.

The dielectric layer 250 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The photodiodes 112 of the pixel sensors 100 are included in the semiconductor layer 248 of the sensor device 208. The photodiodes 112 may each include one or more doped regions of semiconductor layer 248. The semiconductor layer 248 may be doped with a plurality of types of ions to form a p-n junction or a PIN junction (e.g., a junction between a p-type portion, an intrinsic (or undoped) type portion, and an n-type portion) corresponding to a photodiode 112. For example, the semiconductor layer 248 may be doped with an n-type dopant to form a first portion (e.g., an n-type portion) of a photodiode 112 and a p-type dopant to form a second portion (e.g., a p-type portion) of the photodiode 112. A photodiode 112 may be configured to absorb photons of incident light. The absorption of photons causes the photodiode 112 to accumulate a charge (a photocurrent 110) due to the photoelectric effect. Here, photons bombard the photodiode 112, which causes emission of electrons of the photodiode 112. The emission of electrons causes the formation of electron-hole pairs, where the electrons migrate toward the cathode of the photodiode 112 and the holes migrate toward the anode, which produces the photocurrent 110.

The photodiodes 112 may be electrically isolated and/or optically isolated from one another by one or more isolation structures in the semiconductor layer 248. Shallow trench isolation (STI) structures 252 may extend into the semiconductor layer 248 from a bottom side of the semiconductor layer 248 (referred to as the front side of the semiconductor layer 248). The STI structures 252 may include one or more dielectric materials, such as a silicon oxide (SiOₓ), a silicon nitride (SiₓN_{y}), and/or a silicon oxynitride (SiON), among other examples.

The isolation structure 224 may extend into the semiconductor layer 248 from a top side of the semiconductor layer 248 (referred to as the back side of the semiconductor layer 248) over the STI structures 252. The combination of the STI structures 252 and the isolation structure 224 in the semiconductor layer 248 laterally surround the pixel sensors 100 in the semiconductor layer 248 (as shown in FIG. 2B) and provide the electrical isolation and/or optical isolation for the pixel sensors 100 in the semiconductor layer 248. Because the isolation structure 224 extends into the semiconductor layer 248 from the back side of the semiconductor layer 248, the isolation structure 224 may be referred to as a backside DTI (BDTI) structure. Alternatively, the isolation structure 224 may be formed from the front side of the semiconductor layer 248 so that the isolation structure 224 extends into the semiconductor layer 248 from the front side. In these implementations, the isolation structure 224 may be referred to as a frontside DTI (FDTI) structure.

The isolation structure 224 may include elongated segments that extend into the semiconductor layer 248. Each segment of the semiconductor layer 248 may include a fill layer 254 and one or more liner layers between the fill layer 254 and the semiconductor layer 248. For example, a liner layer 256 may be included between the fill layer 254 and the semiconductor layer 248, and another liner layer 258 may be included between the liner layer 256 and the semiconductor layer 248. In some implementations, the liner layer 258 is omitted, such that the liner layer 256 is in contact with the fill layer 254 and the semiconductor layer 248. In some implementations, another liner layer is included between the liner layer 258 and the semiconductor layer 248.

The fill layer 254 of the isolation structure 224 may include a silicon oxide (SiOₓ such as SiO₂), phosphosilicate glass (PSG), borophosphosilicate glass (BPSG), fluorinated silica glass (FSG), another low dielectric constant (low-k) dielectric material having a dielectric constant of approximately 3.9 or less, and/or another dielectric material. The fill layer 254 may be deposited as a bulk dielectric layer that fills in trenches in which the isolation structure 224 is formed.

The liner layers 256, 258 may each include conformal layers that are conformally deposited on the sidewalls and bottom surfaces of the trenches in which the isolation structure 224 is formed. The liner layers 256, 258 may each include a high dielectric constant (high-k) dielectric material having a dielectric constant that is greater than approximately 3.9. In some implementations, the liner layers 256, 258 include different dielectric materials. For example, the liner layer 256 may include a silicon nitride (SiₓN_{y}, such as Si₃N₄) material, and the liner layer 258 may include an aluminum oxide (AlₓO_{y}, such as Al₂O₃) material. In these implementations, the band gap of the material of the liner layer 256 (e.g., silicon nitride) may be less than the band gap of the material of the liner layer 256 (e.g., aluminum oxide). In some implementations, the liner layers 256, 258 include the same dielectric material. For example, the liner layers 256, 258 may both include an aluminum oxide (AlₓO_{y}) material and may have approximately the same band gap.

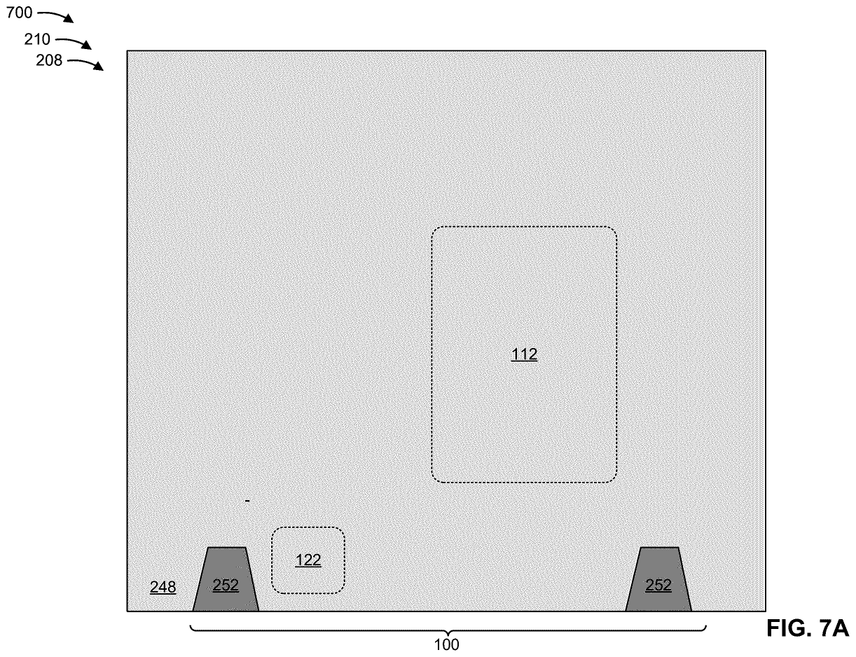

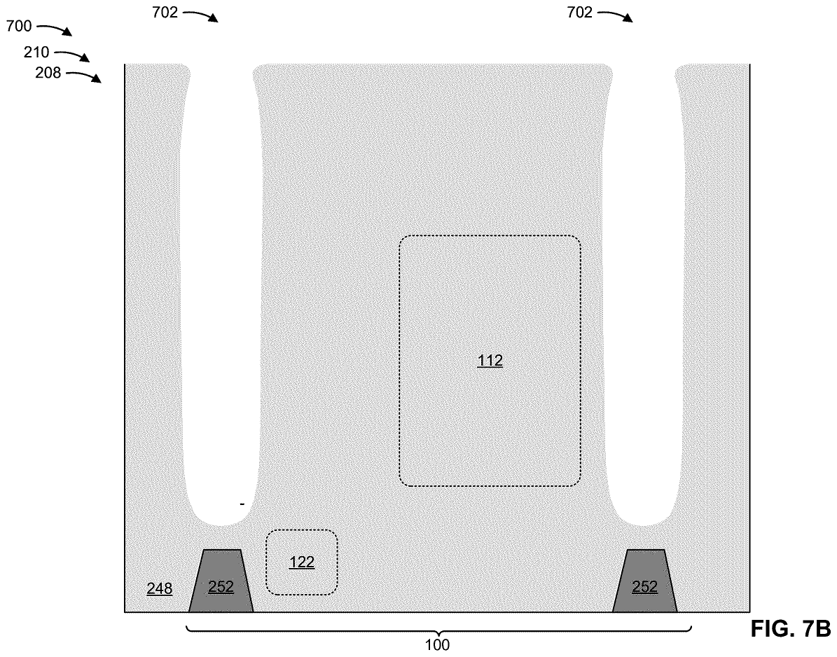

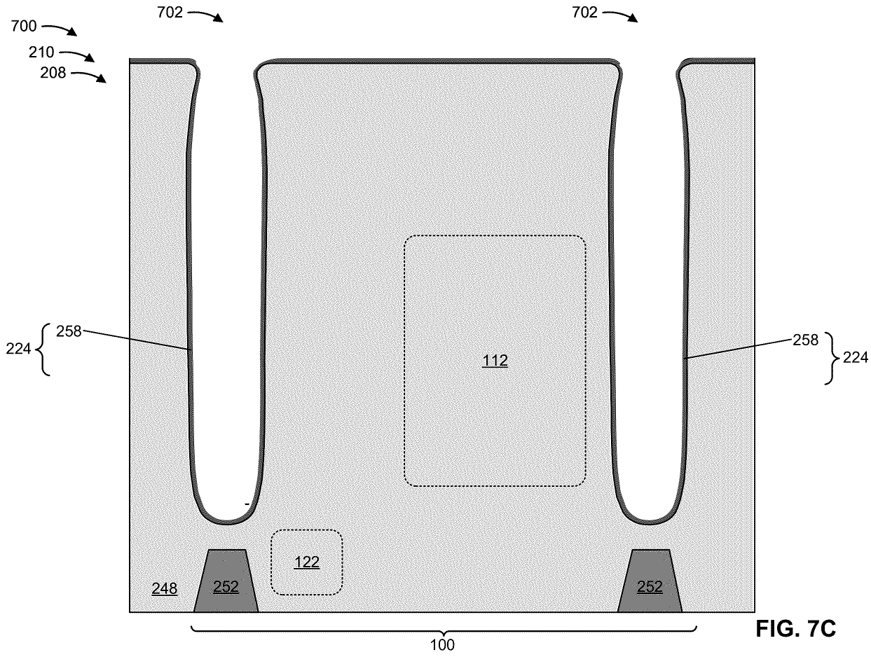

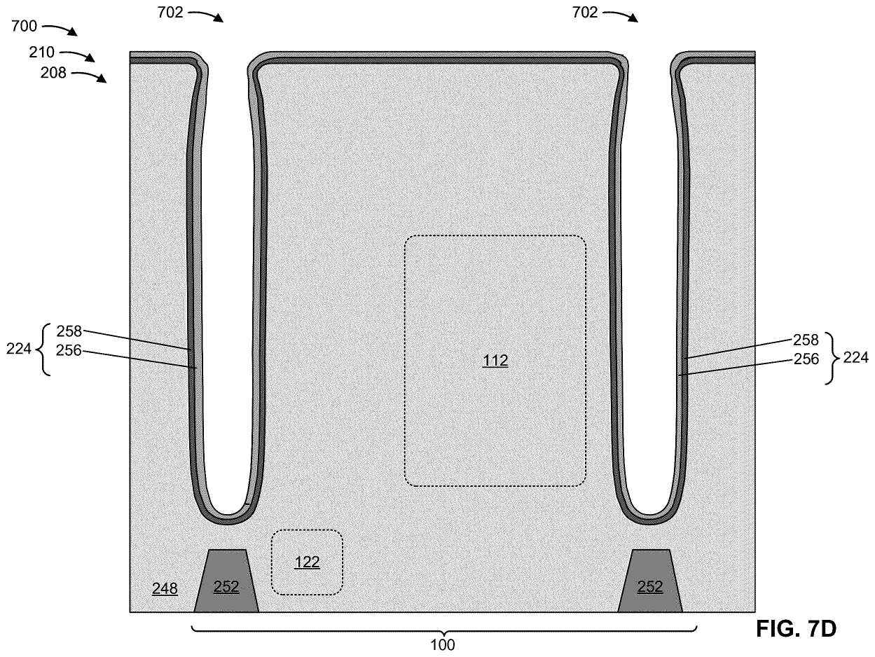

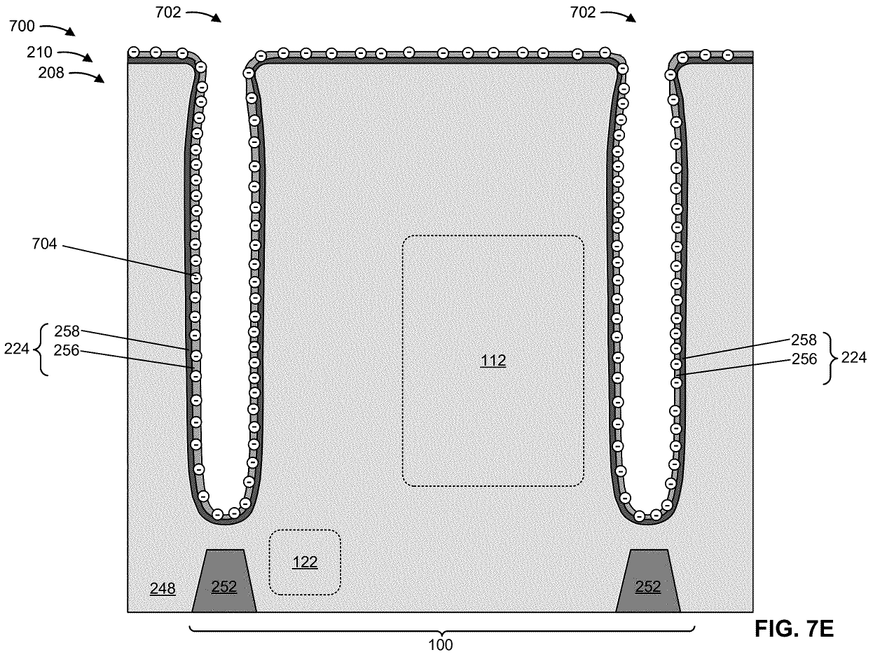

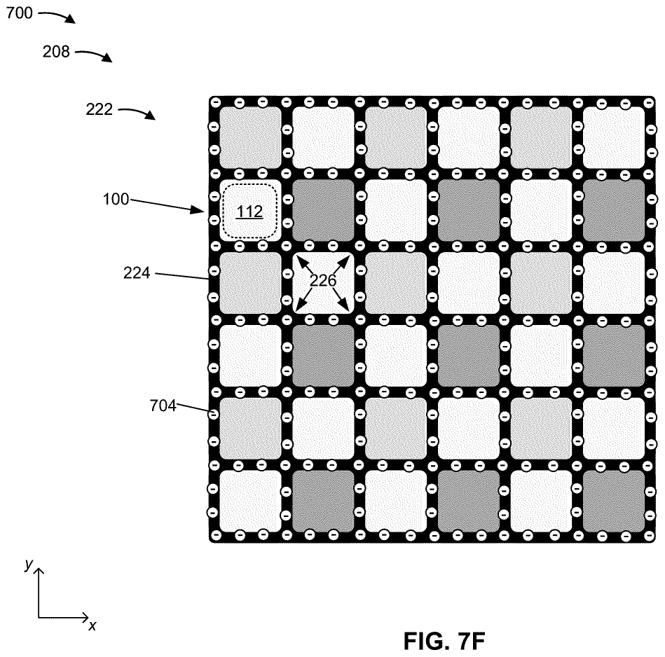

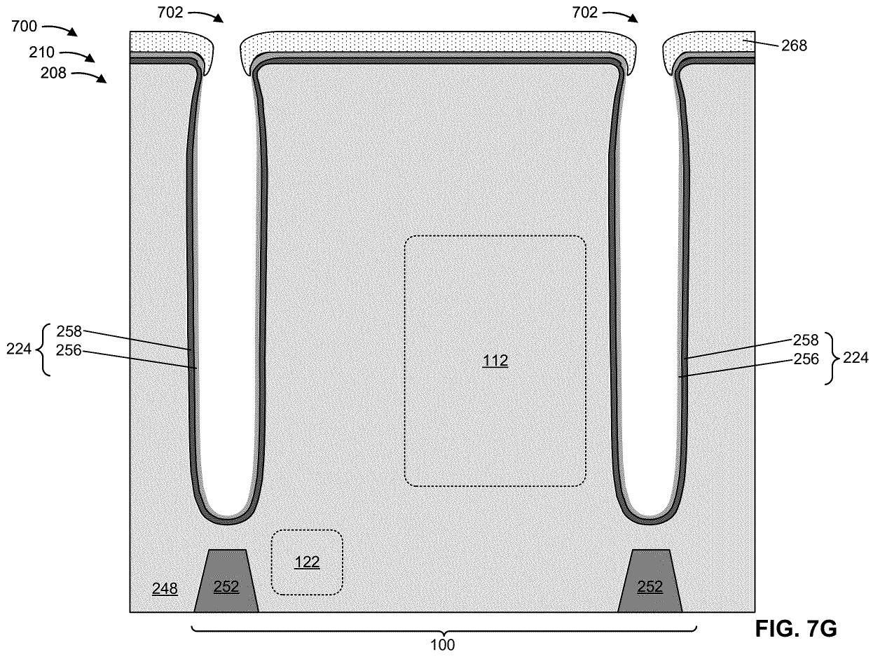

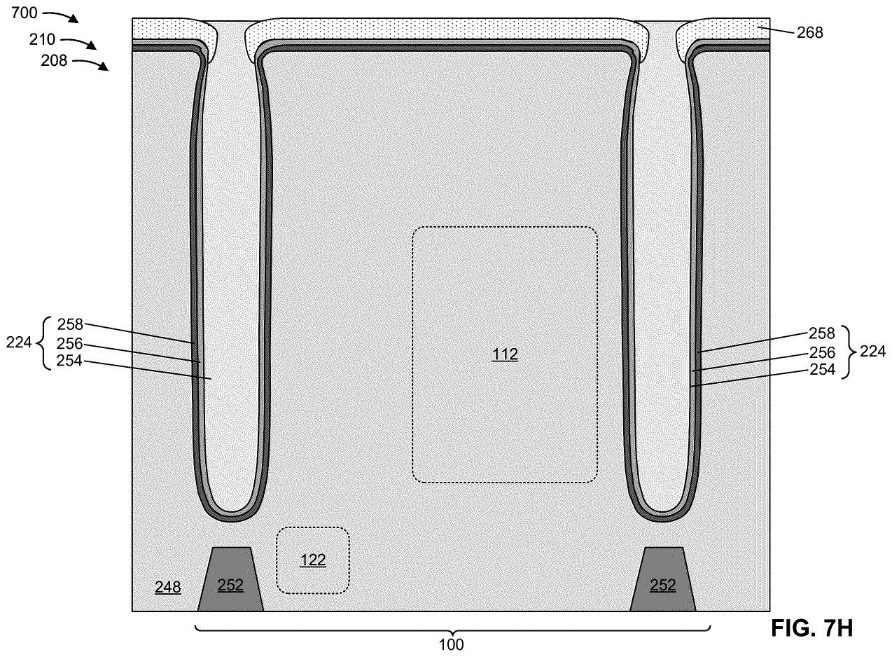

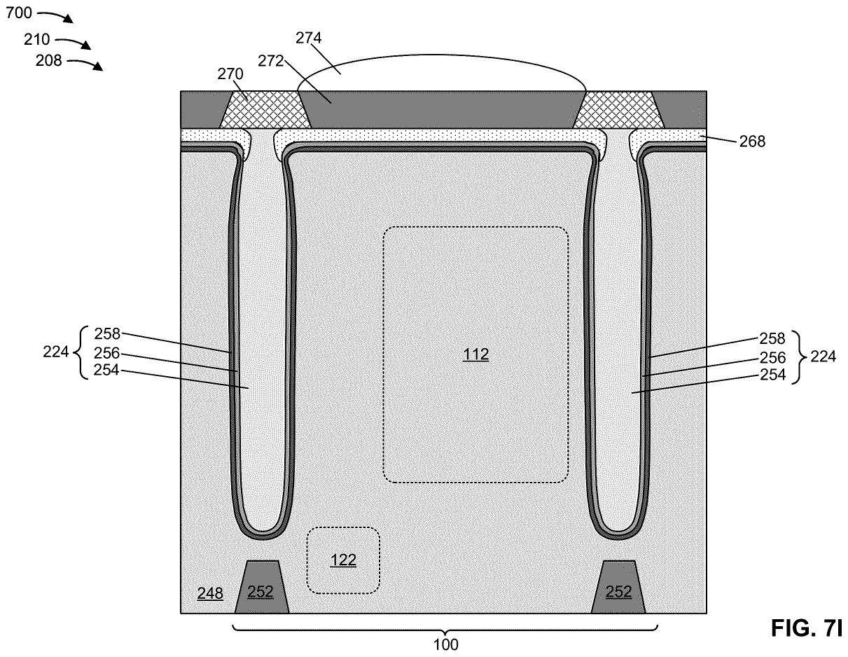

The material of the liner layer 256 may be doped with hydrogen (H) and may therefore have a greater hydrogen concentration than the material of the liner layer 258, than the material of the fill layer 254, and/or than the material of the semiconductor layer 248. As described in connection with FIGS. 7A-7I, the material of the liner layer 256 may be in-situ doped (or doped using another technique) with hydrogen (e.g., hydrogen-doped silicon nitride (SiₓN_{y}: H such as Si₃N₄: H)), and a treatment operation may be performed on the liner layer 256 to cause silicon-hydrogen (Si—H) bonds in the liner layer 256 to be broken. This causes at least a portion of the hydrogen of the material of the liner layer 256 to diffuse through the liner layer 258 and into the portions of the semiconductor layer 248 around the segments of the isolation structure 224. The hydrogen that diffuses from the liner layer 256 and into the surrounding portions of the semiconductor layer 248 may passivate dangling bonds in the surrounding portions of the semiconductor layer 248 that may have formed as a result of etching the semiconductor layer 248 to form the trenches for the isolation structure 224.

Because of the hydrogen diffusion from the material of the liner layer 256, the material of the liner layer 256 may have a net electronegativity. The high hydrogen concentration in the as-deposited material of the liner layer 256 may be positively charged (e.g., may have a negative flat-band voltage (V_{fb})), and the material of the liner layer 256 may become negatively charged (e.g., may have a positive flat-band voltage) as a result of the treatment operation. For example, the as-deposited material of the liner layer 256 may have a fixed charge density of approximately 3×10¹¹ charge carriers per cubic meter to approximately 5×10¹² charge carriers per cubic meter, whereas the material of the liner layer 256 may have a fixed charge density of approximately −7×10¹² charge carriers per cubic meter to approximately −6×1012 charge carriers per cubic meter. However, other values and ranges are within the scope of the present disclosure. The treatment operation may also lower the valance band (E_{V}) and the conduction band (E_{C}) of the material of the semiconductor layer 248 in that the negative charging of the liner layer 256 may reverse the band bending at the interface between the liner layer 256 and the semiconductor layer 248.

In the example 200 of the image sensor device 210, the isolation structure 224 may be included in the backside of the semiconductor layer 248. On the front side of the semiconductor layer 248, transfer gates 114 of the pixel sensors 100 are included, and the dielectric layer 250 is included over the transfer gates 114. The transfer gates 114 are electrically connected to the interconnect layer 218, which enables inputs (e.g., gate voltages) to be provided to the transfer gates 114 to control the flow of photocurrents 110 from the photodiodes 112 to floating diffusion nodes 122 of pixel sensors 100.

The interconnect layer 218 may include a dielectric layer 260, a bonding layer 262, a plurality of interconnect structures 264 in the dielectric layer 260, and a plurality of bonding structures 266 in the bonding layer 262. The dielectric layer 260 may include one or more ILD layers, one or more IMD layers, and/or one or more ESLs, among other examples. The dielectric layer 260 and the bonding layer 262 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 264 may each include conductive lines, trenches, vias, interconnects, metallization layers, and/or other types of electrically conductive structures that electrically connect the transfer gates 114 to one or more other regions of the sensor device 208 and/or to one or more regions of the processing device 206, among other examples. The bonding structures 266 may each include bonding pads, bonding vias, and/or other types of bonding structures. The interconnect structures 264 and the bonding structures 266 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

At the bonding interface 220, the bonding layers 242 and 262 may be bonded together (e.g., in a dielectric-to-dielectric bond), and the bonding structures 246 and 266 may be bonded together (e.g., in a metal-to-metal bond). In some implementations, a small amount offset between a bonding structure 246 and a bonding structure 266 may occur such that the edges of the bonding structure 246 and a bonding structure 266 are offset relative to each other. Signals and/or power may be provided between the processing device 206 and the sensor device 208 through the bonding structures 246 and 266.

Above the top side (e.g., the backside) of the semiconductor layer 248, an antireflective coating (ARC) layer 268 may be included above the segments of the isolation structure 224. In some implementations, the ARC layer 268 is formed prior to formation of the fill layer 254 of the isolation structure 224, and the ends of the ARC layer 268 extend into a portion of the segments of the isolation structure 224. In some implementations, the ARC layer 268 is formed after the fill layer 254 is formed, and the ARC layer 268 extends over the fill layer 254. The ARC layer 268 may include an oxide material such as tantalum oxide (TaₓO_{y} such as Ta₂O₅), a silicon oxide (SiOₓ such as SiO₂), and/or another suitable oxide material. Additionally and/or alternatively, a silicon nitride (SiNₓ), a silicon carbide (SiCₓ), or a mixture thereof, such as a silicon carbon nitride (SiCN), a silicon oxynitride (SiON), and/or another suitable antireflective material.

A grid structure 270 may be included above the ARC layer 268. Segments of the grid structure 270 may be located over corresponding segments of the isolation structure 224 and may be formed around the perimeter of the photodiodes 112 of the pixel sensors 100. Thus, the grid structure 270 may have a similar overall top view shape and layout as the isolation structure 224. Openings in the grid structure 270 are included above the photodiodes 112 to enable incident light to pass through the grid structure 270 and to the photodiodes 112.

In some implementations, the grid structure 270 is formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples. In some implementations, the grid structure 270 is formed of a dielectric material such as a silicon oxide (SiOₓ) and/or a silicon nitride (SiNₓ), among other examples. In some implementations, the grid structure 270 is a multi-layer structure that includes one or more dielectric layers and one or more metal layers that are stacked and vertically arranged.

Color filter regions 272 of the pixel sensors 100 be included in the openings in the grid structure 270. The color filter regions 272 may be included above the photodiodes 112 of the pixel sensors 100. The color filter regions 272 may be included above the photodiodes 112. Each color filter region 272 may be configured to filter incident light to allow a particular wavelength of the incident light to pass to a photodiode 112. For example, a color filter region 272 may filter incident light to allow red light to pass through the color filter region 272 to an associated photodiode 112. As another example, a color filter region 272 may filter incident light to allow green light to pass through the color filter region 272 to an associated photodiode 112. As another example, a color filter region 272 may filter incident light to allow blue light to pass through the color filter region 272 to an associated photodiode 112. In some implementations, a color filter region 272 may be non-discriminating or non-filtering, which may define a white pixel sensor. A non-discriminating or non-filtering color filter region 272 may include a material that permits all wavelengths of light to pass into the associated photodiode 112 (e.g., for purposes of determining overall brightness to increase light sensitivity for the image sensor). In some implementations, a color filter region 272 may be an NIR bandpass color filter region 272, which may define an NIR pixel sensor. An NIR bandpass color filter region 272 may include a material that permits the portion of incident light in an NIR wavelength range to pass to an associated photodiode 112 while blocking visible light from passing.

Micro-lenses 274 may be included over and/or on the color filter regions 272. The micro-lenses 274 may include a respective micro-lens for each of the pixel sensors 100. A micro-lens may be formed to focus incident light toward a photodiode 112 of an associated pixel sensor 100.

As further shown in FIG. 2C, a metal layer 276 may be included above the semiconductor layer 248 in the BLC region 228 of the semiconductor layer 248. The metal layer 276 may be included as a light-blocking layer to prevent incident light from entering the portion of semiconductor layer 248 in the BLC region 228. The portion of semiconductor layer 248 in the BLC region 228 is thus a sensing region that is kept “dark” so that dark current measurements may be performed in the BLC region 228. A dark current measurement may be performed to measure the amount of charge (dark current) in the semiconductor layer 248 that is generated from sources other than incident light (e.g., from thermal energy in the semiconductor layer 248) so that the dark current measurement may be used for black level correction (or black level calibration) for the pixel sensor array 222.

As further shown in FIG. 2C, the bonding pad region 230 may include a plurality of dielectric layers 278, 280, 282, and 284 that electrically isolate a bonding pad structure 286. The bonding pad structure 286 is electrically coupled and/or physically coupled with one or more of the interconnect structures 264 in the interconnect layer 218 of the sensor device 208. A bonding pad opening 288 is included above the bonding pad structure 286 to enable an external electrical connection to be formed to the bonding pad structure 286.

The plurality of dielectric layers 278, 280, 282, and 284 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples. The bonding pad structure 286 may include a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

The seal ring region 232 includes a plurality of stacked interconnect structures 244 in the interconnect layer 214 and a plurality of stacked interconnect structures 264 in the interconnect layer 218 to seal the structures and layers of the image sensor device 210 to prevent ingress of humidity and other contaminants, as well as to provide structural rigidity to the image sensor device 210.

As indicated above, FIGS. 2A-2C are provided as examples. Other examples may differ from what is described with regard to FIGS. 2A-2C.

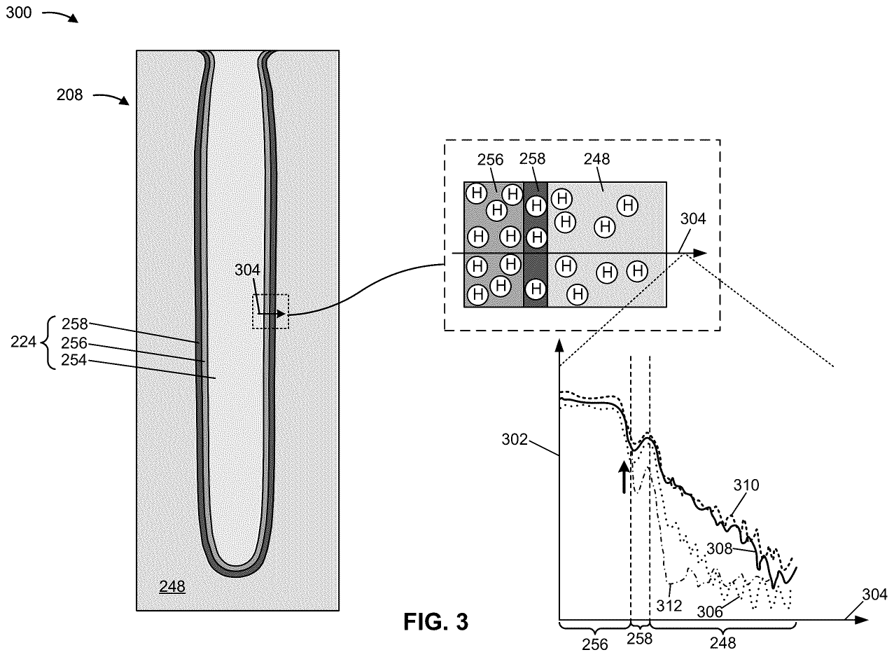

FIG. 3 is a diagram of an example 300 of hydrogen concentration in a sensor device 208 described herein. As described in connection with FIGS. 7A-7I, the liner layer 256 may be formed by depositing a material with a high hydrogen (H) concentration on the sidewalls and bottom surface of the trenches in which the isolation structure 224 is formed, and a treatment operation may be performed to break silicon-hydrogen (Si—H) bonds in the material of the liner layer 256. This causes hydrogen to migrate from the liner layer 256 into the liner layer 258 and/or into the semiconductor layer 248 around the trenches, as shown in FIG. 3.

FIG. 3 further illustrates various example implementations of hydrogen concentration 302 along a direction 304 across a portion of the isolation structure 224, which is approximately perpendicular to the liner stack that includes the liner layers 256 and 258. The direction 304 may correspond to a direction of hydrogen diffusion from the liner layer 256 to the semiconductor layer 248.

As shown in FIG. 3, hydrogen signals 306, 308, and 310 along the direction 304 show that the hydrogen concentrations 302 in the semiconductor layer 248 near the isolation structure 224 are greater when a material having a high hydrogen concentration is used for the liner layer 256 than when another type of material is used (which is represented by the hydrogen signal 312 in FIG. 3). This is because hydrogen from the liner layer 256 diffuses through the liner layer 258 and into the surrounding semiconductor layer 248.

The hydrogen signal 306 is an example where no treatment operation is performed in connection with the high hydrogen concentration material. The hydrogen signal 308 is an example where a treatment operation is performed in connection with the high hydrogen concentration material, and where the as-deposited hydrogen concentration in the liner layer 256 is greater than for the hydrogen signal 306. The hydrogen signal 310 is an example where a treatment operation is performed in connection with the high hydrogen concentration material, and where the as-deposited hydrogen concentration in the liner layer 256 is greater than for the hydrogen signal 308.

As shown by the hydrogen signals 306, 308, and 310, the treatment operation causes the hydrogen concentration 302 in the semiconductor layer 248 to be greater than a hydrogen concentration without the treatment operation. This is due to silicon-hydrogen bonds being broken in the liner layer 256 during the treatment operation, which enables hydrogen to migrate from the liner layer 256 to the semiconductor layer 248. Moreover, the treatment operation causes hydrogen to diffuse further into the semiconductor layer 248. Thus, the hydrogen concentration 302 in the semiconductor layer 248 around the segments of the isolation structure 224 may exhibit a gradient in which the hydrogen concentration 302 is greatest at the interface between the semiconductor layer 248 and the isolation structure 224, and decreases away from the isolation structure 224.

As indicated above, FIG. 3 is provided as an example. Other examples may differ from what is described with regard to FIG. 3.

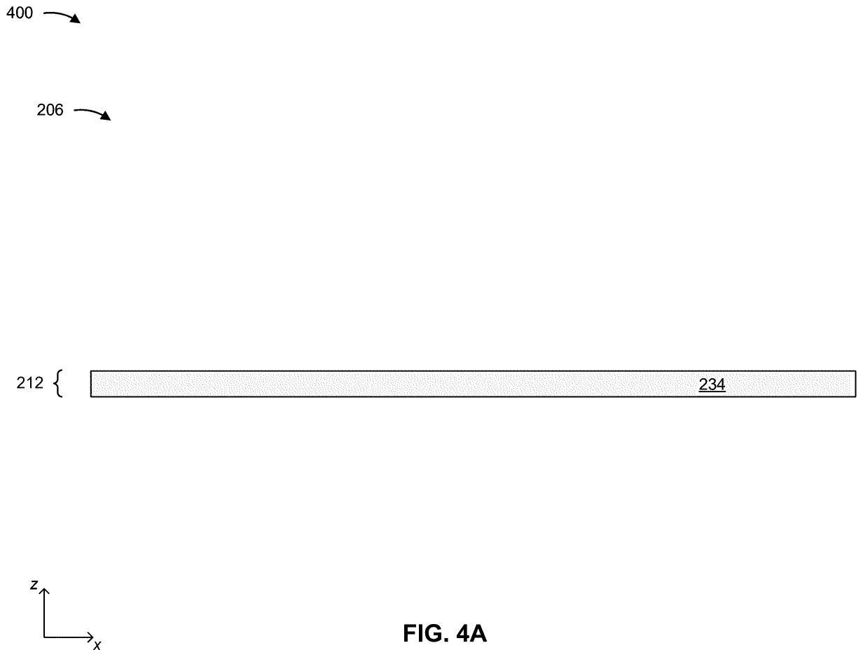

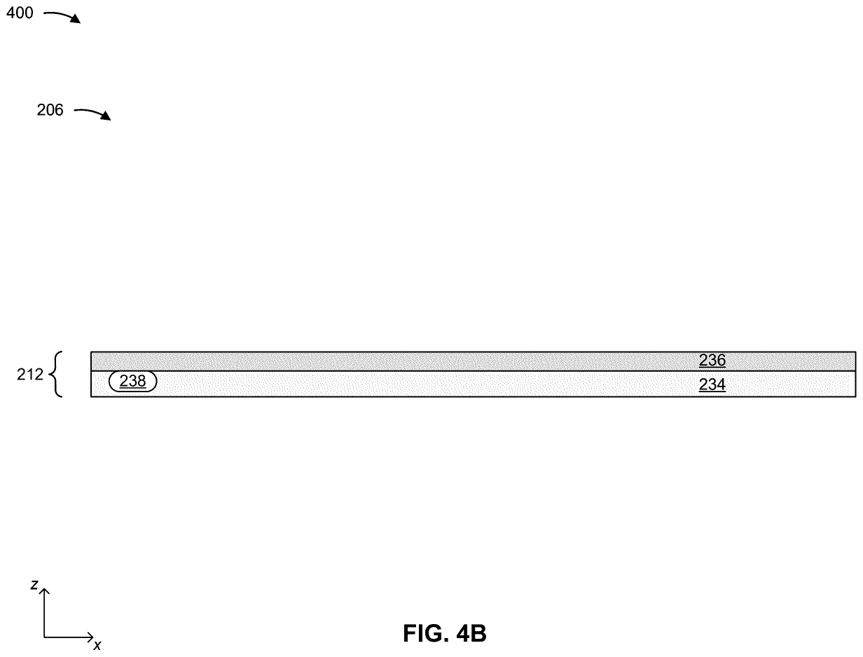

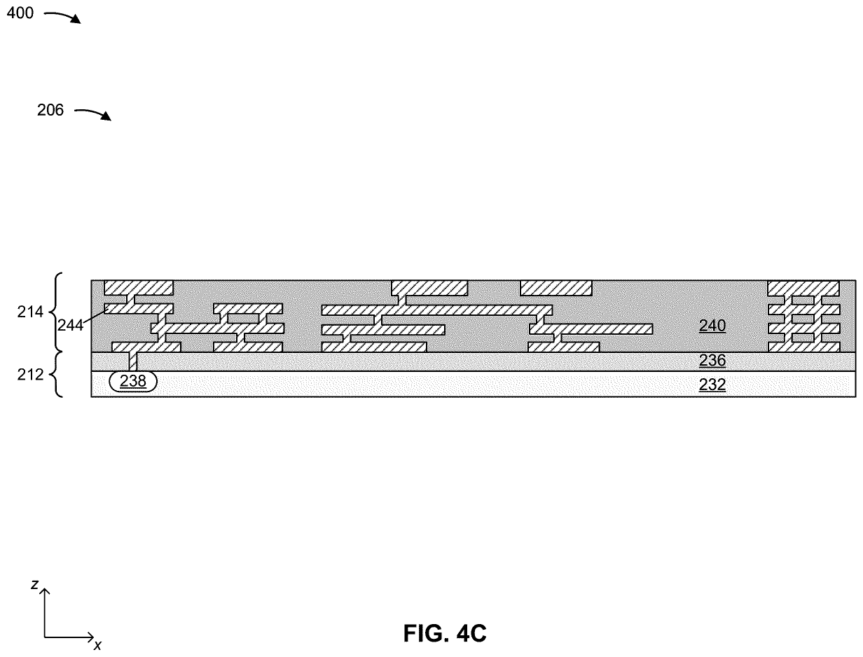

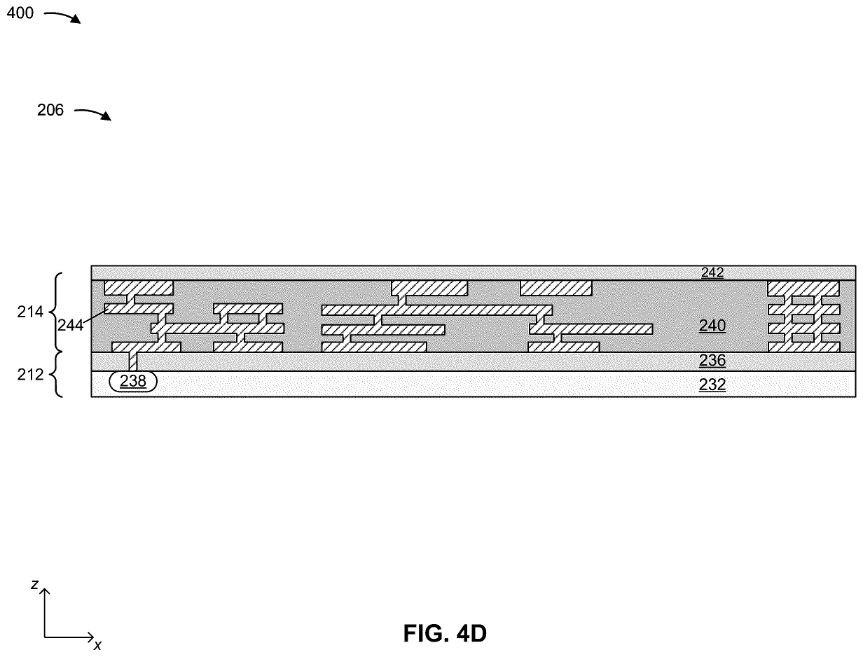

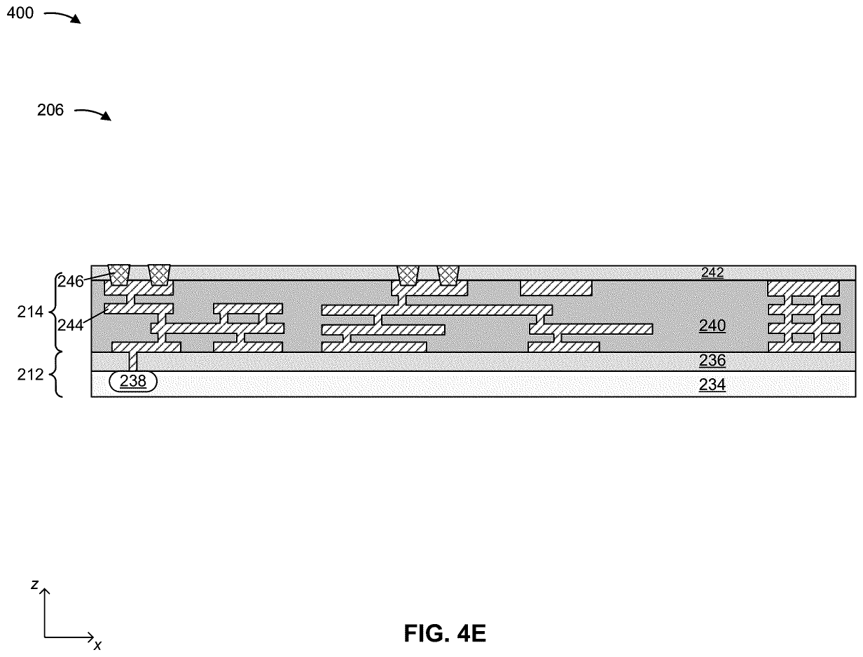

FIGS. 4A-4E are diagrams of an example implementation 400 of forming a processing device 206 (or a portion thereof) described herein. In some implementations, one or more of the semiconductor processing operations described in connection with FIGS. 4A-4E may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 4A, the semiconductor layer 234 of the device layer 212 of the processing device 206 is provided. The semiconductor layer 234 may be provided in the form of a semiconductor wafer such as a silicon (Si) wafer. In some implementations, the semiconductor layer 234 is provided in the form of a layer of an SOI wafer. In some implementations, the semiconductor layer 234 is provided as another type of semiconductor work piece.

As shown in FIG. 4B, one or more integrated circuit devices 238 may be formed in and/or on the semiconductor layer 234. One or more semiconductor processing tools may be used to form one or more portions of the integrated circuit devices 238. For example, a deposition tool may be used to perform various deposition operations to deposit layers of the integrated circuit devices 238, and/or to deposit photoresist layers for etching the semiconductor layer 234 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer 234 and/or portions of the deposited layers to form the integrated circuit devices 238. As another example, a planarization tool may be used to planarize portions of the integrated circuit devices 238. As another example, a plating tool may be used to deposit metal structures and/or layers of the integrated circuit devices 238.

As further shown in FIG. 4B, a dielectric layer 236 may be deposited over and/or on the semiconductor layer 234 and over and/or on the integrated circuit devices 238. A deposition tool may be used to deposit the dielectric layer 236 using a physical vapor deposition (PVD) technique, an atomic layer deposition (ALD) technique, a chemical vapor deposition (CVD) technique, an oxidation technique, another type of deposition technique. In some implementations, a planarization tool may be used to planarize the dielectric layer 236 after the dielectric layer 236 is deposited.

As shown in FIG. 4C, a first portion of an interconnect layer 214 of the processing device 206 is formed above the device layer 212. To form the first portion of the interconnect layer 214, a deposition tool may be used to deposit a dielectric layer 240 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 240 after the dielectric layer 240 is deposited.

A deposition tool, an exposure tool, a developer tool, an etch tool, a planarization tool, a plating tool, and/or another semiconductor processing tool may be used to perform various operations to form interconnect structures 244 in the dielectric layer 240 of the first portion of the interconnect layer 214. A deposition tool and/or a plating tool may be used to deposit the interconnect structures 244 using a PVD technique, an ALD technique, a CVD technique, an electroplating technique, and/or another deposition technique. In some implementations, a planarization tool may be used to planarize the interconnect structures 244 after the interconnect structures 244 are deposited.

In some implementations, first portion of the interconnect layer 214 is built up in the z-direction in a plurality of via layers (V-layers) and metallization layers (M-layers). For example, a first portion of the dielectric layer 240 may be formed, recesses may be formed in the first portion of the dielectric layer 240, and first interconnect structures 244 (e.g., a V0 via layer, an M0 metallization layer) may be formed in the recesses. A second portion of the dielectric layer 240 may be formed, recesses may be formed in the second portion of the dielectric layer 240, and second interconnect structures 244 (e.g., a V1 via layer, an M1 metallization layer) may be formed in the recesses. The remaining via layers and/or metallization layers of the first portion of the interconnect layer 214 may be formed in a similar manner.

As shown in FIGS. 4D and 4E, a second portion of the interconnect layer 214 may be formed, and the second portion of the interconnect layer 214 may include a bonding layer 242 and bonding structures 246. As shown in FIG. 4D, the bonding layer 242 may be formed over and/or on the dielectric layer 240, and over and/or on the top-most interconnect structures 244. A deposition tool may be used to deposit the bonding layer 242 using a PVD technique, an ALD technique, a CVD technique, an oxidation technique, another deposition technique. In some implementations, a planarization tool may be used to planarize the bonding layer 242 after the bonding layer 242 is deposited.

As shown in FIG. 4E, the bonding structures 246 may be formed in the bonding layer 242. For example, a deposition tool, an exposure tool, and a developer tool may be used to form a patterned masking layer on the bonding layer 242. An etch tool may be used to etch the bonding layer 242 (e.g., using a wet etch technique, a dry etch technique) to form recesses in the bonding layer 242. A deposition tool and/or a plating tool may be used to deposit the bonding structures 246 in the recess using a CVD technique, a PVD technique, an ALD technique, an electroplating technique, and/or another deposition technique. In some implementations, a planarization tool may perform a planarization operation to planarize the bonding structures 246 after the bonding structures 246 are deposited.

Alternatively, a metal layer may be deposited over the dielectric layer 240 and may be patterned and etched to define the bonding structures 246. Subsequently, the bonding layer 242 may be deposited around and over the bonding structures 246, and the bonding layer 242 may be planarized to reveal the bonding structures 246.

As indicated above, FIGS. 4A-4E are provided as an example. Other examples may differ from what is described with regard to FIGS. 4A-4E.

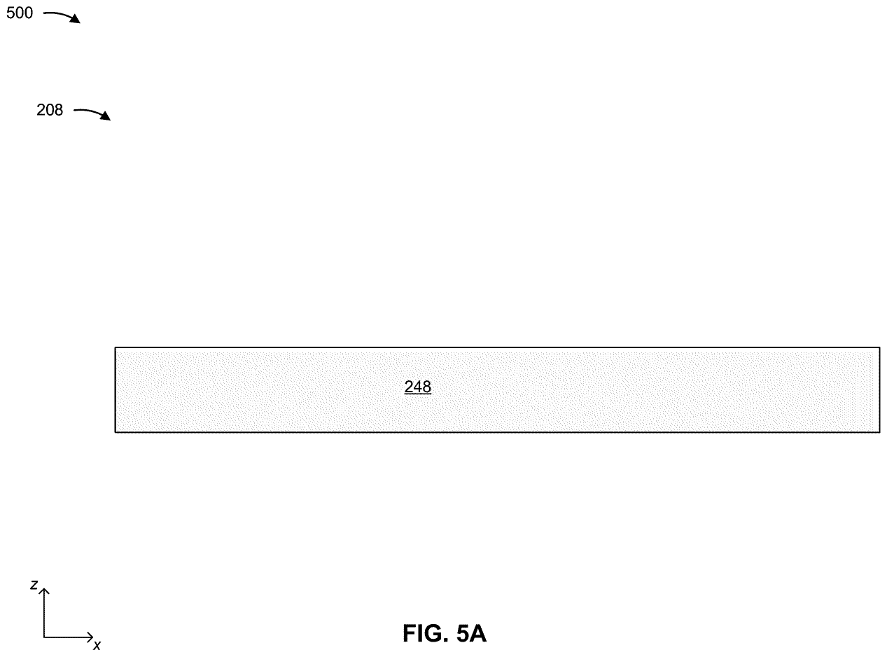

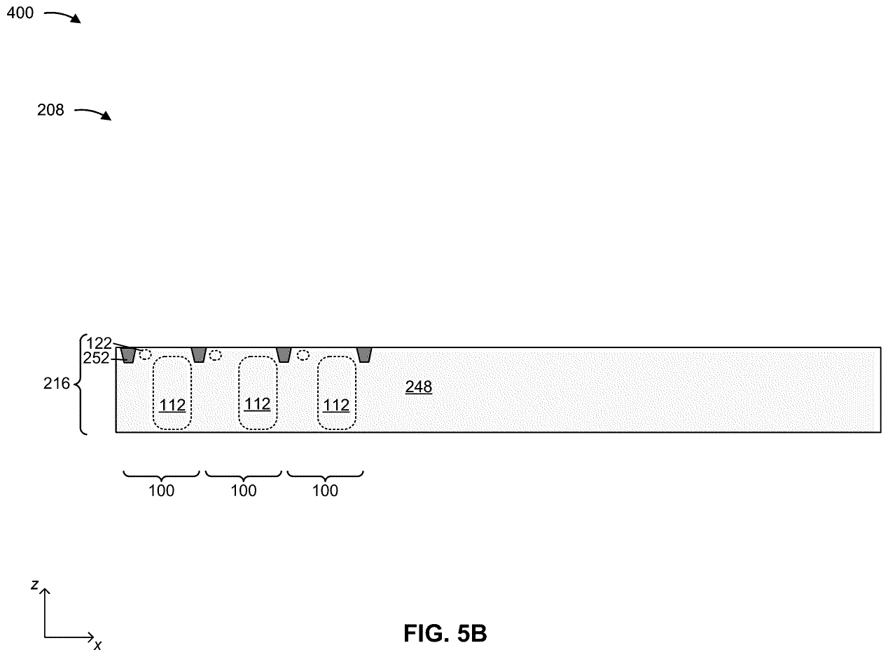

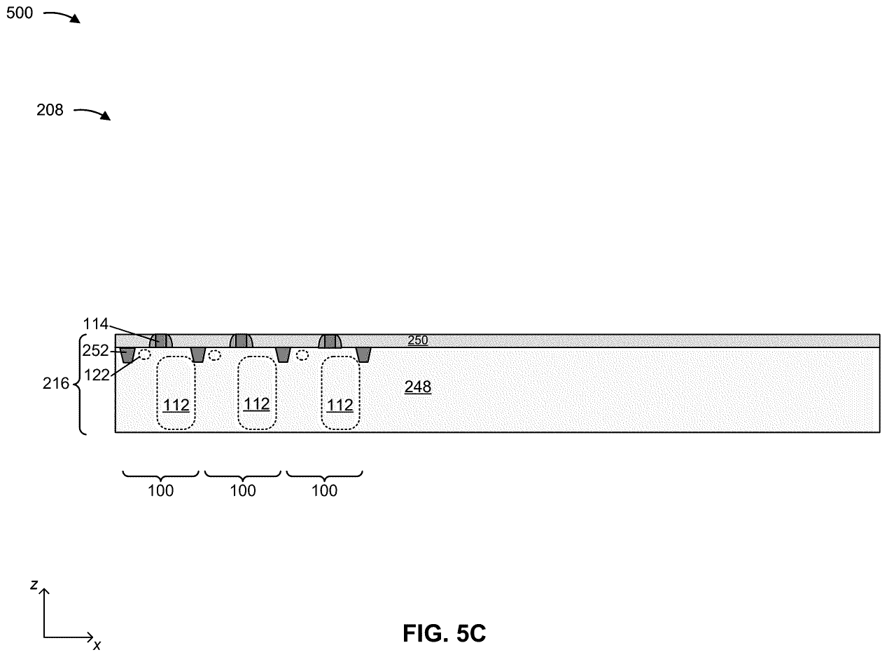

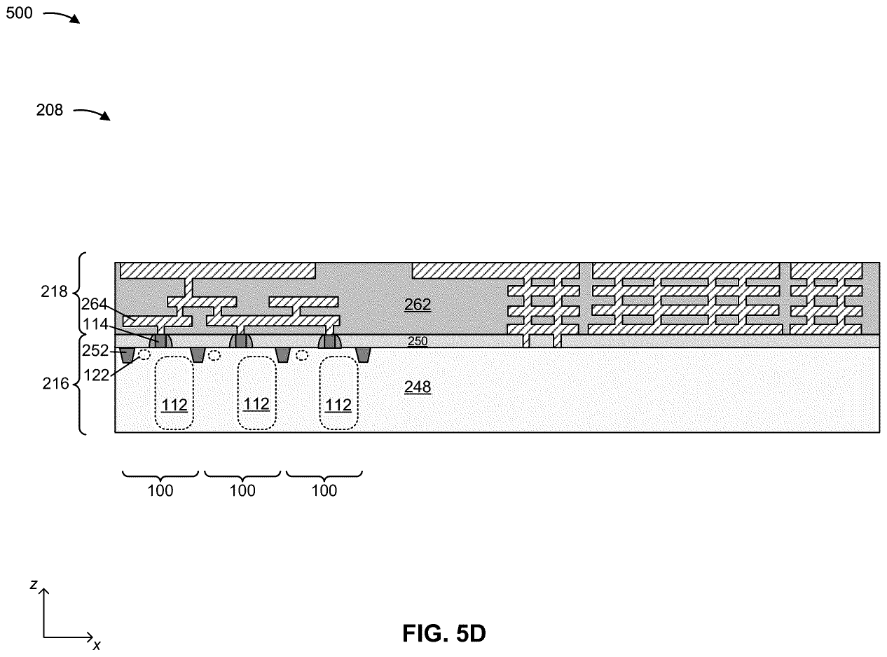

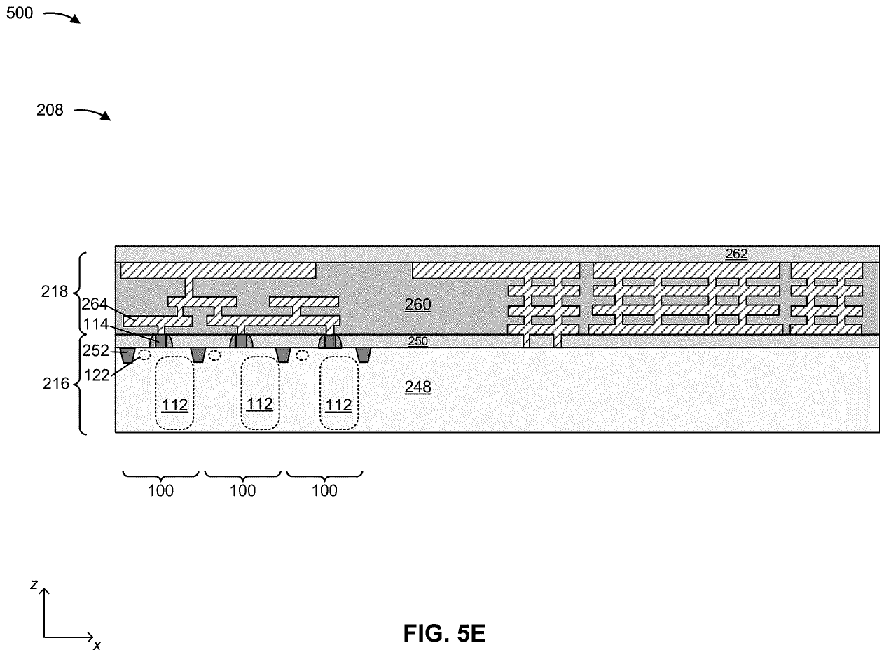

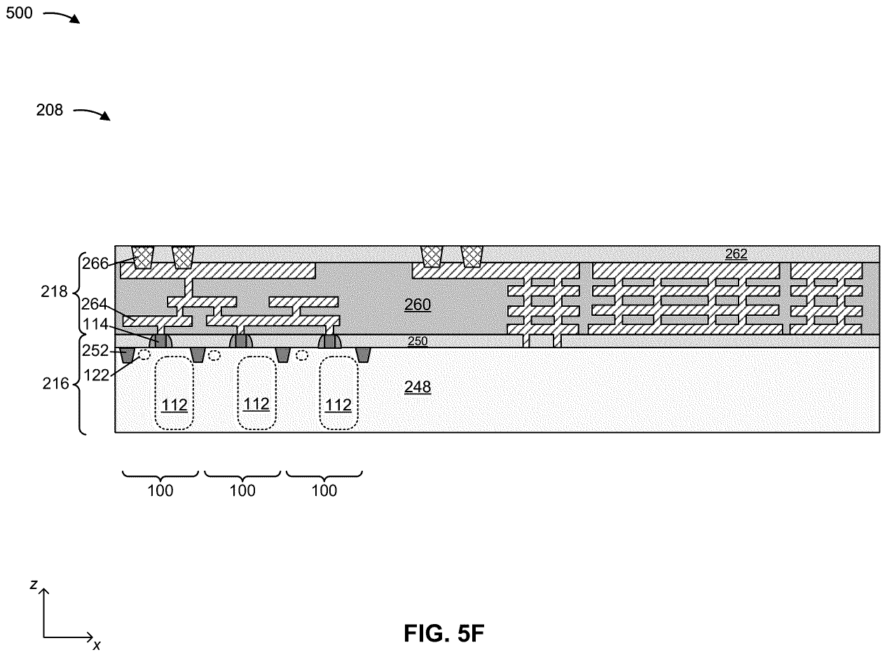

FIGS. 5A-5F are diagrams of an example implementation 500 of forming a sensor device 208 (or a portion thereof) described herein. In particular, the example implementation 500 may include an example frontside process flow for a sensor device 208. In some implementations, one or more of the semiconductor processing operations described in connection with FIGS. 5A-5F may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 5A, the semiconductor layer 248 of the device layer 216 of the sensor device 208 is provided. In some implementations, the semiconductor layer 248 may be provided in the form of a semiconductor wafer such as a silicon (Si) wafer. In some implementations, the semiconductor layer 248 is provided the form of a layer of an SOI wafer. In some implementations, the semiconductor layer 248 is provided in the form of another type of semiconductor work piece.

As shown in FIG. 5B, photodiodes 112 and floating diffusion nodes 122 of pixel sensors 100 of a pixel sensor array 222 of the sensor device 208 may be formed in the semiconductor layer 248 from the frontside of the semiconductor layer 248. In some implementations, an ion implantation tool may be used to implant ions into the semiconductor layer 248 to form a P-N junction between a p-doped region of the semiconductor layer 248 and an n-doped region of the semiconductor layer 248, or to form a P-I-N junction between p-doped region of the semiconductor layer 248, an n-doped region of the semiconductor layer 248, and an intrinsic (e.g., undoped) semiconductor region for a photodiode 112. In some implementations, an ion implantation tool may be used to implant n-type dopants and/or p-type dopants into the semiconductor layer 248 to form the floating diffusion nodes 122.

As further shown in FIG. 5B, STI structures 252 may be formed in the semiconductor layer 248 (e.g., from the front side of the semiconductor layer 248) such that the STI structures 252 are located between the photodiodes 112. In some implementations, the STI structures 252 are formed after the photodiodes 112 are formed. In some implementations, the STI structures 252 are formed prior to formation of the photodiodes 112.

A deposition tool, an exposure tool, and a developer tool may be used to form a patterned masking layer on the semiconductor layer 248. An etch tool may be used to etch into the semiconductor layer 248 from the front side of the semiconductor layer 248 (e.g., using a wet etch technique, a dry etch technique) to form the recesses in the front side of the semiconductor layer 248. A deposition tool may be used to deposit the STI structures 252 in the recesses using a CVD technique, a PVD technique, an ALD technique, an oxidation technique, and/or another deposition technique. In some implementations, a planarization tool may perform a planarization operation to planarize the STI structures 252 after the STI structures 252 are deposited.

As shown in FIG. 5C, transfer gates 114 of the pixel sensors 100 may be formed over and/or on the front side surface of the semiconductor layer 248. Forming a transfer gate 114 may include deposing a gate dielectric on the front side surface of the semiconductor layer 248, depositing a gate electrode on the gate dielectric layer, and/or forming sidewall spacers on sidewalls of the gate electrode, among other examples.

As further shown in FIG. 5C, a dielectric layer 250 may be formed over and/or on the front side of the semiconductor layer 248. In some implementations, the dielectric layer 250 is deposited over and/or on the transfer gates 114. In some implementations, dummy gate structures are formed in place of the transfer gates 114, the dielectric layer 250 is deposited around and/or over the dummy gates, and the dummy gates are subsequently replaced with the transfer gates 114 by forming the transfer gates 114 in recesses in the dielectric layer 250 formed by removal of the dummy gates.

A deposition tool may be used to deposit the dielectric layer 250 using a CVD technique, a PVD technique, an ALD technique, an electroplating technique, and/or another deposition technique. In some implementations, a planarization tool may perform a planarization operation to planarize the dielectric layer 250 after the dielectric layer 250 is deposited.

As shown in FIG. 5D, a first portion of an interconnect layer 218 of the sensor device 208 is formed above the device layer 216. To form the first portion of the interconnect layer 218, a deposition tool may be used to deposit a dielectric layer 260 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 260 after the dielectric layer 260 is deposited.

A deposition tool, an exposure tool, a developer tool, an etch tool, a planarization tool, a plating tool, and/or another semiconductor processing tool may be used to perform various operations to form interconnect structures 264 in the first portion of the interconnect layer 218. A deposition tool and/or a plating tool may be used to deposit the interconnect structures 264 using a PVD technique, an ALD technique, a CVD technique, an electroplating technique, and/or another deposition technique. In some implementations, a planarization tool may be used to planarize the interconnect structures 264 after the interconnect structures 264 are deposited.

In some implementations, first portion of the interconnect layer 218 is built up in the z-direction in a plurality of via layers (V-layers) and metallization layers (M-layers). For example, a first portion of the dielectric layer 260 may be formed, recesses may be formed in the first portion of the dielectric layer 260, and first interconnect structures 264 (e.g., a V0 via layer, an M0 metallization layer) may be formed in the recesses. A second portion of the dielectric layer 260 may be formed, recesses may be formed in the second portion of the dielectric layer 260, and second interconnect structures 264 (e.g., a V1 via layer, an M1 metallization layer) may be formed in the recesses. The remaining via layers and/or metallization layers of the first portion of the interconnect layer 218 may be formed in a similar manner.

As shown in FIGS. 5E and 5F, a second portion of the interconnect layer 218 may be formed, and the second portion of the interconnect layer 218 may include a bonding layer 262 and bonding structures 266. As shown in FIG. 5E, the bonding layer 262 may be formed over and/or on the dielectric layer 260, and over and/or on the top-most interconnect structures 264. A deposition tool may be used to deposit the bonding layer 262 using a PVD technique, an ALD technique, a CVD technique, an oxidation technique, another deposition technique. In some implementations, a planarization tool may be used to planarize the bonding layer 262 after the bonding layer 262 is deposited.

As shown in FIG. 5F, the bonding structures 266 may be formed in the bonding layer 262. For example, a deposition tool, an exposure tool, and a developer tool may be used to form a patterned masking layer on the bonding layer 262. An etch tool may be used to etch the bonding layer 262 (e.g., using a wet etch technique, a dry etch technique) to form recesses in the bonding layer 262. A deposition tool and/or a plating tool may be used to deposit the bonding structures 266 in the recess using a CVD technique, a PVD technique, an ALD technique, an electroplating technique, and/or another deposition technique. In some implementations, a planarization tool may perform a planarization operation to planarize the bonding structures 266 after the bonding structures 266 are deposited.

As indicated above, FIGS. 5A-5F are provided as an example. Other examples may differ from what is described with regard to FIGS. 5A-5F.

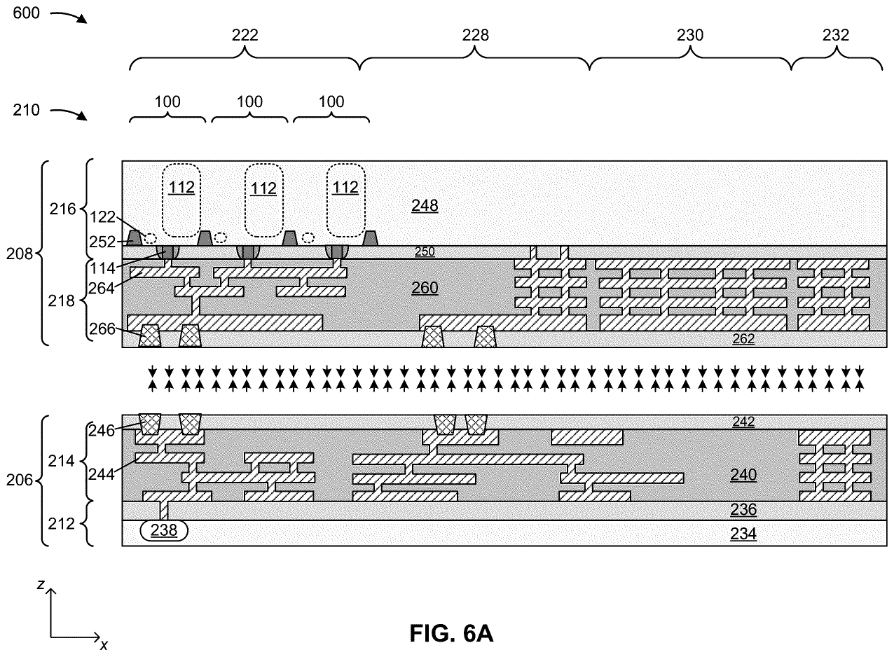

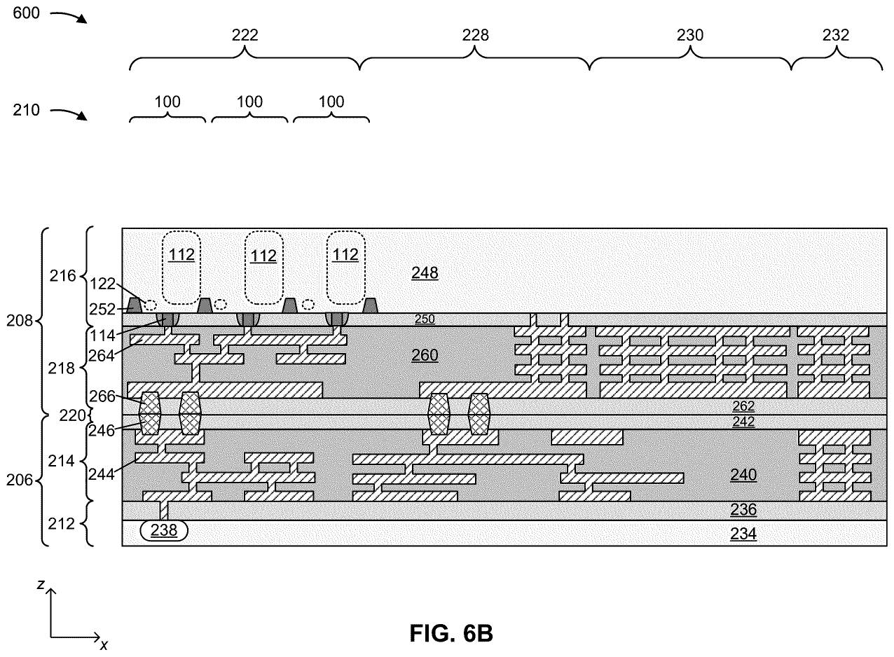

FIGS. 6A and 6B are diagrams of an example implementation 600 of forming an image sensor device 210 (or a portion thereof) described herein. In some implementations, one or more of the semiconductor processing operations described in connection with FIGS. 6A and 6B may be performed using one or more semiconductor processing tools, such as a bonding tool and/or a wafer/die transport tool, among other examples.

As shown in FIGS. 6A and 6B, a bonding operation is performed to bond a processing device 206 and a sensor device 208 to form the image sensor device 210. The processing device 206 and the sensor device 208 may be bonded at a bonding interface 220, which may include the bonding layers 242 and 262 (respectively of the processing device 206 and the sensor device 208), and the bonding structures 246 and 266 (respectively of the processing device 206 and the sensor device 208). A bonding tool may be used to form a dielectric-to-dielectric bond between the bonding layers 242 and 262 at the bonding interface 220, and to form a metal-to-metal bond between the bonding structures 246 and 266 at the bonding interface 220.

As shown in FIG. 6B, after bonding, the processing device 206 and the sensor device 208 are stacked or vertically arranged in the z-direction in the image sensor device 210. The interconnect layer 214 of the processing device 206 and the interconnect layer 218 of the sensor device 208 are facing toward each other in the image sensor device 210, and the device layer 212 of the processing device 206 and the device layer 216 of the sensor device 208 are facing away from each other.

The bonding operation to bond the processing device 206 and the sensor device 208 may be performed at the wafer level, meaning that a plurality of processing devices 206 formed on a processing wafer 202 may be bonded with a corresponding plurality of sensor devices 208 on a sensor wafer 204 to form a plurality of image sensor devices 210. The wafer stack of the bonded processing wafer 202 and sensor wafer 204 may be subsequently diced to singulate the image sensor devices 210.

As indicated above, FIGS. 6A and 6B are provided as an example. Other examples may differ from what is described with regard to FIGS. 6A and 6B.

FIGS. 7A-7I are diagrams of an example implementation 700 of forming a pixel sensor array 222 of a sensor device 208 (or a portion thereof) described herein. In particular, the example implementation 700 may include an example of performing backside processing on a backside of the semiconductor layer 248 of the sensor device 208 to form a backside pixel sensor array 222 for the sensor device 208. In some implementations, one or more of the semiconductor processing operations described in connection with FIGS. 7A-7I may be performed using one or more semiconductor processing tools, such as a deposition tool, an exposure tool, a developer tool, an etch tool, a planarization tool, a plating tool, an ion implantation tool, an annealing tool, a plasma tool, a corona charging tool, and/or a wafer/die transport tool, among other examples.

As shown in FIG. 7A, the semiconductor processing operations described in connection with FIGS. 7A-7I may be performed after frontside processing of the sensor device 208 (illustrated and described in connection with FIGS. 5A-5F) bonding the sensor device 208 and a processing device 206 to form an image sensor device 210 (illustrated and described in connection with FIGS. 6A and 6B). The image sensor device 210 may be flipped and bonded to a carrier substrate (not shown) to permit backside processing of the sensor device 208 to be performed.

As shown in FIG. 7B, trenches 702 may be formed in the backside of the semiconductor layer 248. Thus, the trenches 702 may extend into the semiconductor layer 248 from the backside surface of the semiconductor layer 248. The trenches 702 may be formed such that, in a top view of the backside of the semiconductor device 208, the trenches 702 intersect to form a grid similar to the isolation structure 224 illustrated in FIG. 2B. The trenches 702 may be formed over the STI structures 252.

In some implementations, a pattern in a photoresist layer is used to etch the semiconductor layer 248 to form the trenches 702. In these implementations, a deposition tool may be used to form the photoresist layer on the backside of the semiconductor layer 248. An exposure tool may be used to expose the photoresist layer to a radiation source to pattern the photoresist layer. A developer tool may be used to develop and remove portions of the photoresist layer to expose the pattern. An etch tool may be used to etch into the backside of the semiconductor layer 248 based on the pattern to form the trenches 702. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique).

In some implementations, the etch operation includes a deep reactive ion etch process. For example, a first etch operation may be performed to etch the semiconductor layer 248 to form the trenches 702 to a first depth in the semiconductor layer 248. A protective layer may be formed on the sidewalls of the trenches 702. The portion of the protective layer on the bottoms of the trenches 702 may be removed, and a second operation may be performed to etch the semiconductor layer 248 to increase the depth of the trenches 702 to a second depth in the semiconductor layer 248. The protective layer may protect the sidewalls of the trenches 702 from being etched, and therefore may prevent, minimize, and/or otherwise reduce lateral expansion of the trenches 702. These operations may be performed for a plurality of cycles to form the trenches 702 to have a high aspect ratio between depths of the trenches 702 and lateral widths of the trenches 702.

As shown in FIG. 7C, the material of the liner layer 258 of the isolation structure 224 may be conformally deposited on the sidewalls and on the bottom surfaces of the trenches 702. A deposition tool may be used to deposit the material of the liner layer 258 using a conformal deposition technique such as CVD and/or ALD. However, other deposition techniques may be used to deposit the material of the liner layer 258.

In some implementations, the material of the liner layer 258 is also deposited over the backside surface of the semiconductor layer 248. In these implementations, the liner layer 258 may extend across the backside surface of the semiconductor layer 248 between the trenches 702.

As shown in FIG. 7D, the material of the liner layer 256 of the isolation structure 224 may be conformally deposited over the sidewalls and over the bottom surfaces of the trenches 702. In particular, the material of the liner layer 256 may be deposited on the liner layer 258 in the trenches 702. A deposition tool may be used to deposit the material of the liner layer 256 using a conformal deposition technique such as CVD and/or ALD. However, other deposition techniques may be used to deposit the material of the liner layer 256.

In some implementations, the material of the liner layer 256 is also deposited over the backside surface of the semiconductor layer 248. In these implementations, the liner layer 256 may extend across the backside surface of the semiconductor layer 248 between the trenches 702.

The material of the liner layer 256 may be doped with hydrogen (H). In some implementations, the material of the liner layer 256 is in-situ doped, meaning the material of the liner layer 256 is doped as the material of the liner layer 256 is deposited. In these implementations, a hydrogen (H₂) gas may be used to in-situ dope the material of the liner layer 256 as the material of the liner layer 256 is deposited. In some implementations, the material of the liner layer 256 is deposited and then doped.

As shown in FIG. 7E, a treatment operation may be performed for the liner layer 256 to negatively charge the material of the liner layer 256. The treatment operation results in the material of the liner layer 256 transitioning from being positively charged to negatively charged. The transformation to being negatively charged results in hydrogen in the material of the liner layer 256 being replaced with electrons 704. As shown in a top view in FIG. 7F, the electrons 704 may diffuse into the segments of the isolation structure 224, as well as into the rounded corners 226 of the isolation structure 224.

The treatment operation may be performed to break hydrogen bonds in the material of the liner layer 256 so that hydrogen diffuses from the material of the liner layer 256 and into the surrounding areas of the semiconductor layer 248. The diffused hydrogen passivates dangling bonds in the surrounding areas of the semiconductor layer 248 (e.g., that may have occurred because of etching the semiconductor layer 248 to form the trenches 702), and the electrons 704 bond with the material of the liner layer 256 in place of the diffused hydrogen.

In some implementations, the treatment operation includes using an annealing tool to perform an annealing operation such as a rapid thermal anneal (RTA) operation. The RTA operation may include rapidly heating the material of the liner layer 256 to break the bonds between the hydrogen and the material of the liner layer 256. For example, the material of the liner layer 256 may include hydrogen-doped silicon nitride (SiₓN_{y}:H), and the RTA operation may cause silicon-hydrogen (Si—H) bonds in the material of the liner layer 256 to be broken. In some implementations, the RTA operation may be performed to heat the material of the liner layer 256 to a temperature that is included in a range of approximately 400 degrees Celsius to approximately 900 degrees Celsius to cause silicon-hydrogen (Si—H) bonds in the material of the liner layer 256 to be broken. However, other values and ranges are within the scope of the present disclosure.

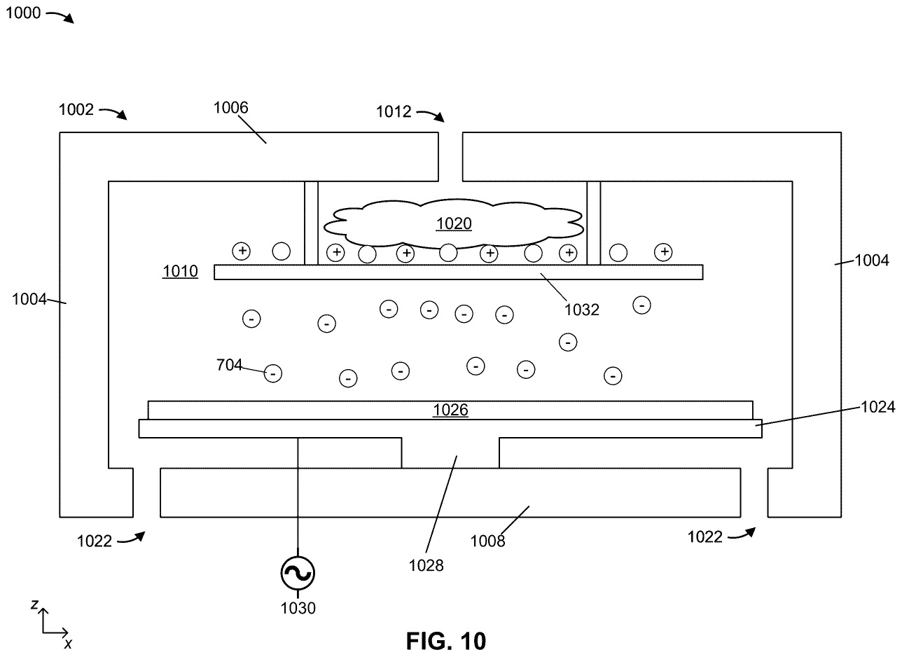

In some implementations, the treatment operation includes using a plasma tool or a corona charging tool to perform a corona charging operation to inject the electrons 704 into the material of the liner layer 256. The electrons 704 are injected to break the silicon-hydrogen (Si—H) bonds in the material of the liner layer 256 and to replace the hydrogen. An example corona charging operation is described in connection with FIG. 10.

As shown in FIG. 7G, the ARC layer 268 may be formed over the backside of the semiconductor layer 248. The ARC layer 268 may be deposited on the liner layer 256. The ends of the ARC layer 268 may extend into a portion of the trenches 702. A deposition tool may be used to deposit the material of the ARC layer 268 using a deposition technique such as PVD that has a high deposition rate, which may result in a low step coverage for the material of the ARC layer 268. This may reduce and/or minimize the amount of material that is deposited into the trenches 702. However, the material of the ARC layer 268 may be deposited using another deposition technique.

As shown in FIG. 7H, the trenches 702 may be filled in with the material of the fill layer 254 of the isolation structure 224. A deposition tool may be used to deposit the material of the fill layer 254 on the liner layer 256 in the trenches using a CVD technique, a PVD technique, an ALD technique, and/or another suitable deposition technique.

As shown in FIG. 7I, the grid structure 270 may be formed over and/or on the ARC layer 268. A deposition tool may be used to deposit one or more layers of material on the ARC layer 268 using a CVD technique, a PVD technique, an ALD technique, an electroplating technique, and/or another suitable deposition technique. The one or more layers may be patterned using lithography techniques and etched to form the grid structure 270. The color filter regions 272 may be formed in the openings in the grid structure 270, and the micro-lenses 274 may be formed on the color filter regions 272.

As indicated above, FIGS. 7A-7I are provided as an example. Other examples may differ from what is described with regard to FIGS. 7A-7I.

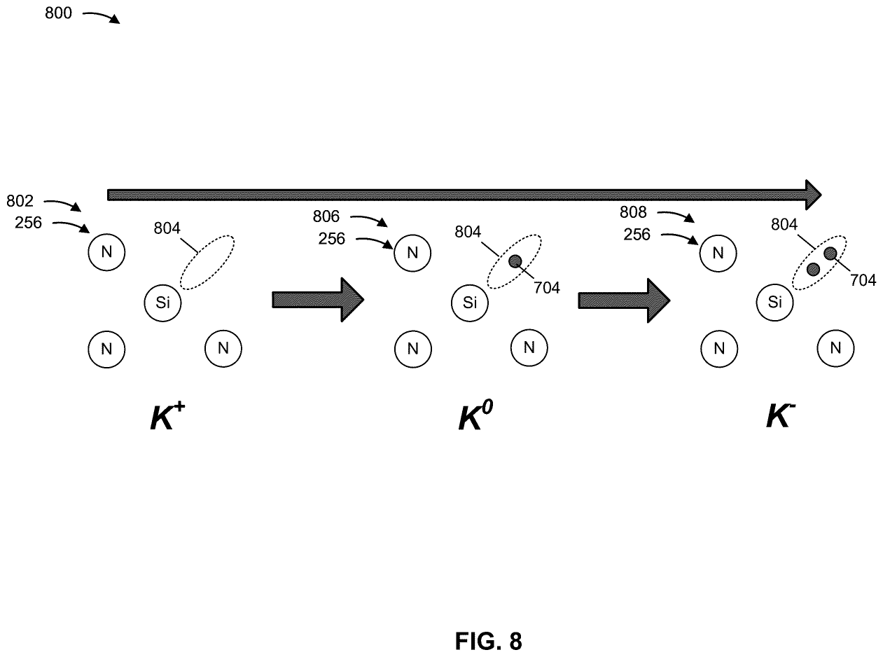

FIG. 8 is a diagram of an example implementation 800 of negatively charging a material of a liner layer 256 of an isolation structure 224 described herein. As shown in FIG. 8, at 802, the as-deposited material of the liner layer 256 may have a K⁺ positive charge. The as-deposited material of the liner layer 256 may be doped with hydrogen (H) at bonding sites 804 of the silicon nitride (Si₃N₄) material of the liner layer 256.

As further shown in FIG. 8, at 806, the treatment operation described in connection with FIGS. 7A-7I results in silicon-hydrogen (Si—H) bonds in the material of the liner layer 256 being broken. This opens up the bonding sites 806 for the hydrogen to be replaced with the electrons 704. The hydrogen may migrate from the liner layer 256 into the semiconductor layer 248 surrounding the isolation structure 224.

As shown in FIG. 8, at 808, additional electrons 704 attach to the open bonding sites 806 of the material of the liner layer 256. The material of the liner layer 256 may transition from being neutrally charged (K0) at 804 to negatively charged (K−) at 808.

As indicated above, FIG. 8 is provided as an example. Other examples may differ from what is described with regard to FIG. 8.

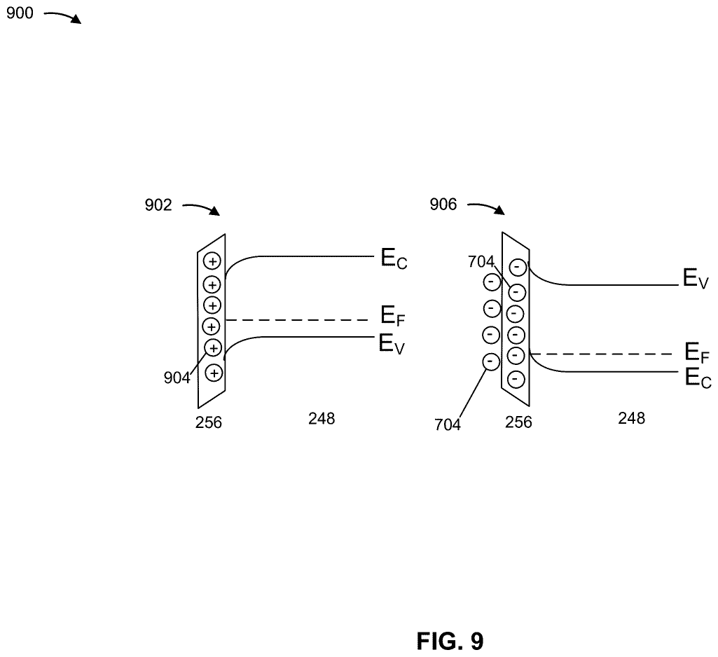

FIG. 9 is a diagram of an example implementation 900 of negatively charging a material of a liner layer 256 of an isolation structure 224 described herein. As shown in FIG. 9, at 902, the as-deposited material of the liner layer 256 may have a positive charge 904. As a result, the material of the semiconductor layer 248 at the interface between the liner layer 256 and the semiconductor layer 248 may exhibit upward band bending in the valance band (E_{V}) and in the conduction band (E_{C}).

As further shown in FIG. 9, at 906, the treatment operation described in connection with FIGS. 7A-7I may inject electrons 704 into the material of the liner layer 256, which may result in silicon-hydrogen (Si—H) bonds in the material of the liner layer 256 being broken. This opens up the bonding sites 806 for the hydrogen to be replaced with the electrons 704. This results in the material of the liner layer 256 having a negative charge. As a result, the material of the semiconductor layer 248 at the interface between the liner layer 256 and the semiconductor layer 248 may exhibit downward band bending in the valance band (E_{V}) and in the conduction band (E_{C}) of the material of the semiconductor layer 248.

As indicated above, FIG. 9 is provided as an example. Other examples may differ from what is described with regard to FIG. 9.

FIG. 10 is a diagram of an example semiconductor processing tool 1000 described herein. The semiconductor processing tool 1000 may be a plasma tool or another type of corona charging tool that may be used to perform the treatment operation of the liner layer 256 described in connection with FIGS. 7E and 7F. In particular, the semiconductor processing tool 1000 may be used to inject electrons into the liner layer 256 to break silicon-hydrogen (Si—H) bonds in the material of the liner layer 256 to negatively charge the material of the liner layer 256.

As shown in FIG. 10, the semiconductor processing tool 1000 includes a processing chamber 1002. The processing chamber 1002 may include sidewalls 1004, an upper cover 1006, and a chamber floor 1008 that define an inner volume 1010 in which semiconductor substrates are processed. In some implementations, the processing chamber 1002 further includes a door or another type of access point through which semiconductor substrates are provided into, and removed from, the processing chamber 1002. In some implementations, the upper cover 1006 is removable from the sidewalls 1004 to provide access into the processing chamber 1002 for maintenance, troubleshooting, and/or cleaning.

At the top of the processing chamber 1002, an inlet 1012 may be located in the upper cover 1006. The inlet 1012 may be an opening through the upper cover 1006 through which processing gases flow, and/or a plasma flows, into the processing chamber 1002. In some implementations, the semiconductor processing tool 1000 is remotely coupled, and a plasma 1020 is generated by a remote plasma source and provided into the processing chamber 1002 through the inlet 1012. In some implementations, the plasma 1020 is generated within the processing chamber 1002, and gases and other reactants for generating the plasma 1020 are provided into the processing chamber through the inlet 1012. The semiconductor processing tool 1000 may be configured to generate the plasma 1020 using a capacitively coupled plasma (CCP) source, an inductively coupled plasma (ICP) source, a microwave source, and/or another type of a plasma source.

At the bottom of the processing chamber 1002, one or more vent ports 1022 may be located in the chamber floor 1008. The vent port(s) 1022 include openings through the chamber floor 1008 through which byproducts may flow out of the processing chamber 1002. In some implementations, the vent port(s) 1022 are coupled to vacuum pumps (not shown) that generate a negative pressure in the processing chamber 1002 to facilitate the flow of byproducts downward toward the vent port(s) 1022.

The vent port(s) 1022 may be located below a chuck 1024 that is located in the processing chamber 1002. The chuck 1024 may include a platform that is sized and/or shaped to accommodate a wafer stack 1026 on the chuck 1024. For example, the wafer stack 1026 may be a round semiconductor wafer stack, and the chuck 1024 may be a round platform that conforms to the shape of the wafer stack 1026. The wafer stack 1026 may include a processing wafer 202 bonded to a sensor wafer 204, and therefore may include a plurality of image sensor devices 210 that each include processing device 206 and a sensor device 208. The chuck 1024 may be an electrostatic chuck that is configured to secure the wafer stack 1026 by an electrostatic clamping force, a vacuum chuck that is configured to secure the wafer stack 1026 by a vacuum clamping force, and/or another type of chuck that is configured to secure the wafer stack 1026 by another type of clamping force.

The chuck 1024 may be supported in the processing chamber 1002 by a pedestal 1028. In some implementations, the pedestal 1028 is configured to rotate the chuck 1024 so as to rotate the wafer stack 1026 on the chuck 1024 during a treatment operation such as a corona charging operation. The chuck 1024 may be coupled to a radio frequency (RF) source 1030, which may be used to apply an electrical bias to the chuck 1024 for controlling the flow of electrons 704 from the plasma 1020 toward the wafer stack 1026.

A filter 1032 may be included within the processing chamber 1002 above the chuck 1024. The filter 1032 may be located vertically between the chuck 1024 and the inlet 1012 in the upper cover 1006 of the processing chamber 1002 so that the filter 1030 can filter subatomic particles from the plasma 1020 so that particular type(s) of subatomic particles pass through the filter 1032. For example, the filter 1032 may filter protons and neutrons from the plasma 1020 so that electrons 704 pass through the filter 1032 and flow toward the wafer stack 1026 on the chuck 1024 during the treatment operation described in connection with FIGS. 7E and 7F. The electrons 704 may be injected into the liner layers 256 on the sensor wafer 204 so that corona charging in the form of charge accumulation occurs in the liner layers 256.

As indicated above, FIG. 10 is provided as an example. Other examples may differ from what is described with regard to FIG. 10.

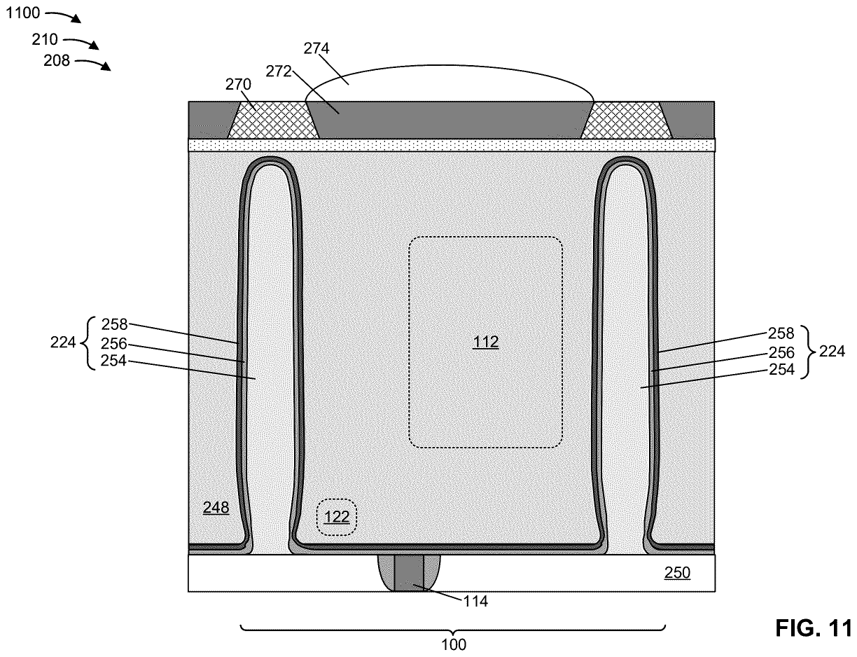

FIG. 11 is a diagram of an example implementation 1100 of a pixel sensor 100 that may be included in a sensor device 208 of an image sensor device 210 described herein. The example implementation 1100 of the pixel sensor 100 illustrated in FIG. 11 includes a similar arrangement and combination as the pixel sensors 100 illustrated in FIGS. 2A-2C. However, in the example implementation 1100, the pixel sensor 100 includes an isolation structure 224 that was formed in, and extends into the semiconductor layer 248 from, the frontside of the semiconductor layer 248.

The isolation structure 224 in the example implementation 1100 of the pixel sensor 100 illustrated in FIG. 11 may include the fill layer 254 and the liner layers 256, 258, where the liner layer 256 includes a negatively charged material such as negatively charged silicon nitride (SiₓN_{y} such as Si₃N₄) and/or negatively charged aluminum oxide (AlₓO_{y} such as Al₂O₃).

The isolation structure 224 (e.g., the frontside DTI structure) in the example implementation 1100 of the pixel sensor 100 illustrated in FIG. 11 may be formed in a similar manner as described in connection with FIGS. 7A-7I. However, the operations to form the isolation structure 224 in the example implementation 1100 of the pixel sensor 100, particularly those illustrated and described in connection with FIGS. 7B-7F and 7H, may be performed as part of frontside processing of the sensor device 208 illustrated in FIGS. 5A-5F. In other words, the isolation structure 224 in the example implementation 1100 of the pixel sensor 100 may be formed prior to bonding the processing device 206 and the sensor device 208, as illustrated in FIGS. 6A and 6B. In some implementations, the operations illustrated and described in connection with FIGS. 7B-7F and 7H may be performed in place of formation of the STI structures 252 (illustrated and described in connection with FIG. 5B) to form the isolation structure 224 in the example implementation 1100 of the pixel sensor 100. The operations illustrated and described in connection with FIGS. 7B-7F and 7H may be performed to form the isolation structure 224 in the example implementation 1100 of the pixel sensor 100 prior to formation of the photodiodes 112 and/or after formation of the photodiodes 112.

As indicated above, FIG. 11 is provided as an example. Other examples may differ from what is described with regard to FIG. 11.

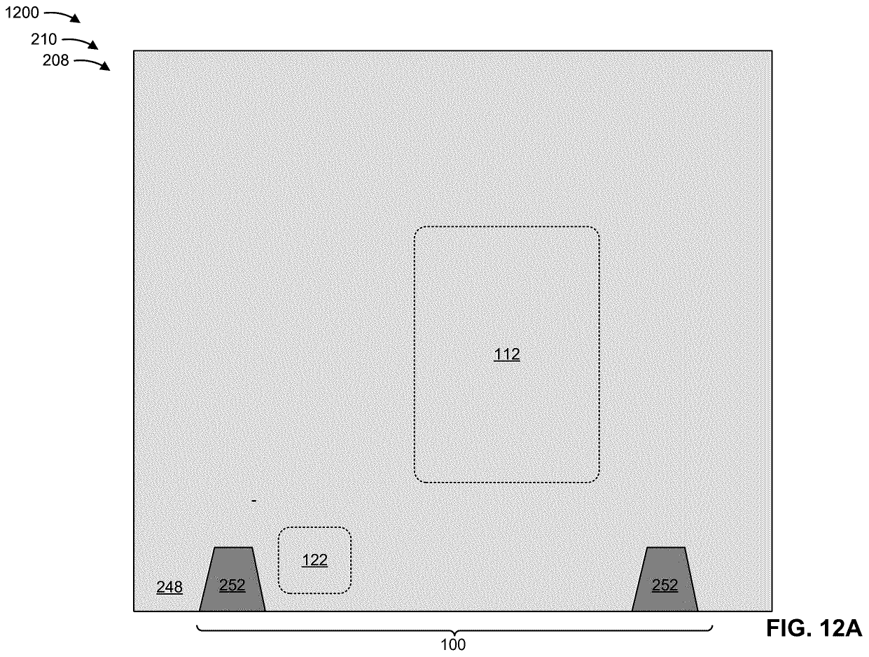

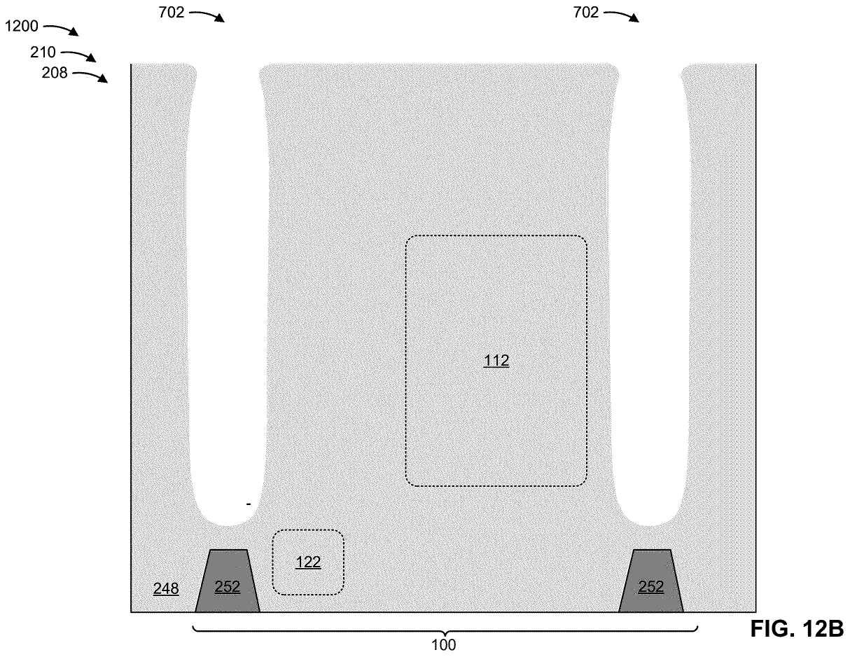

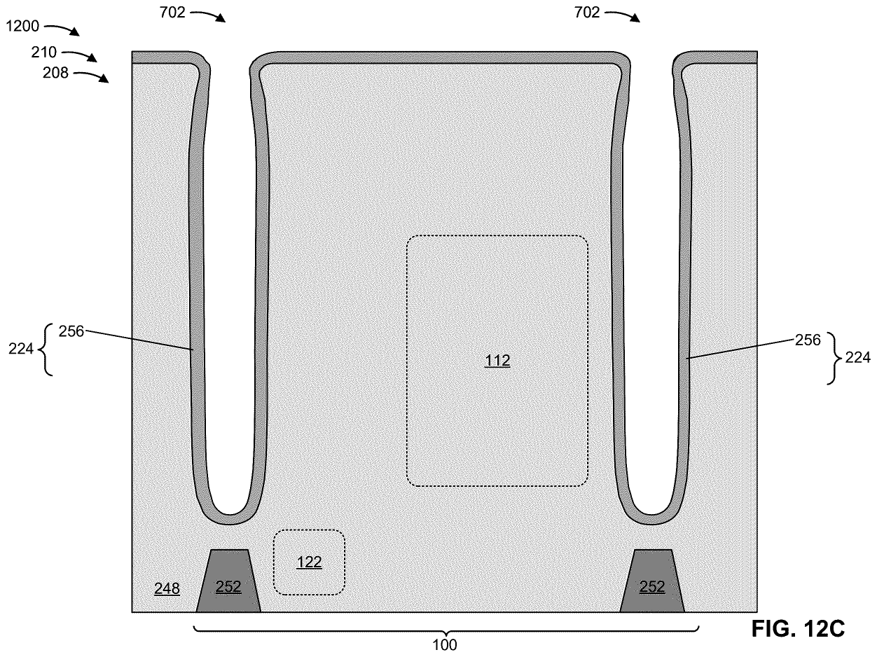

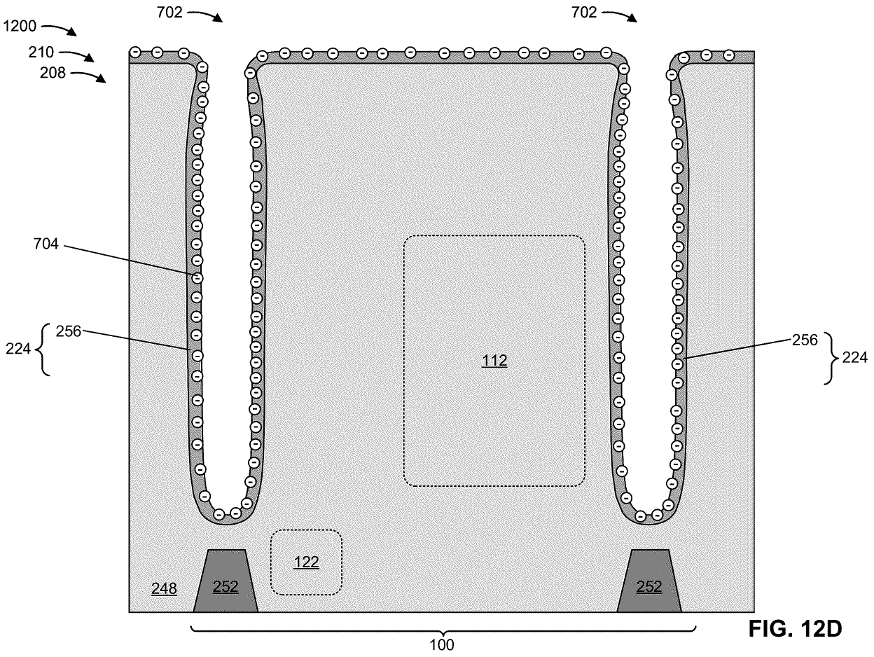

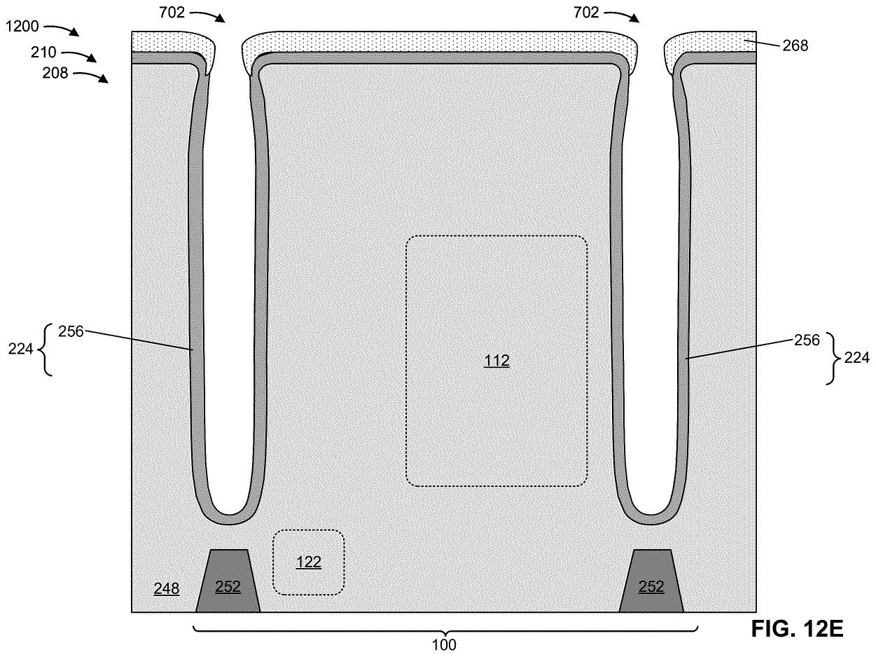

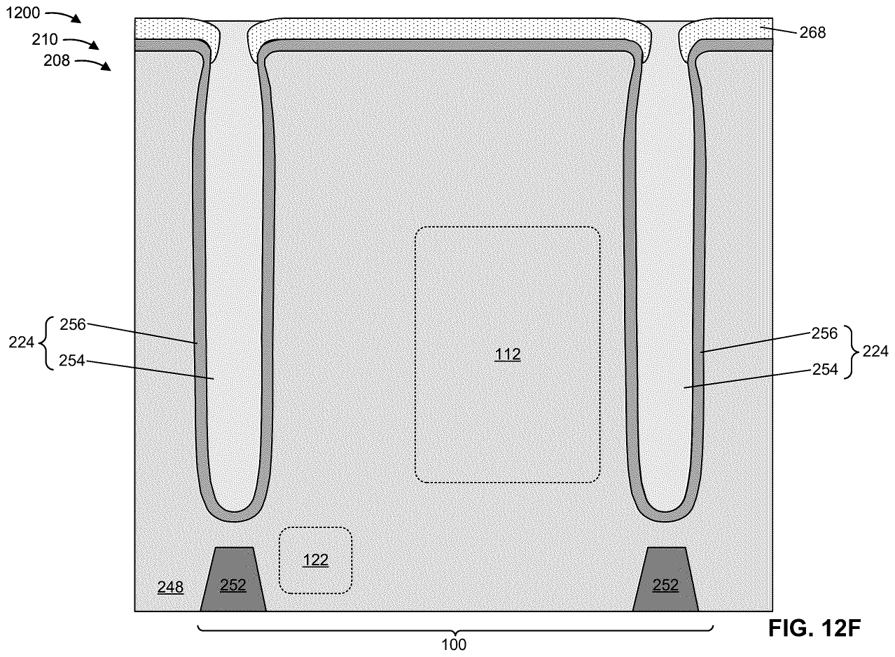

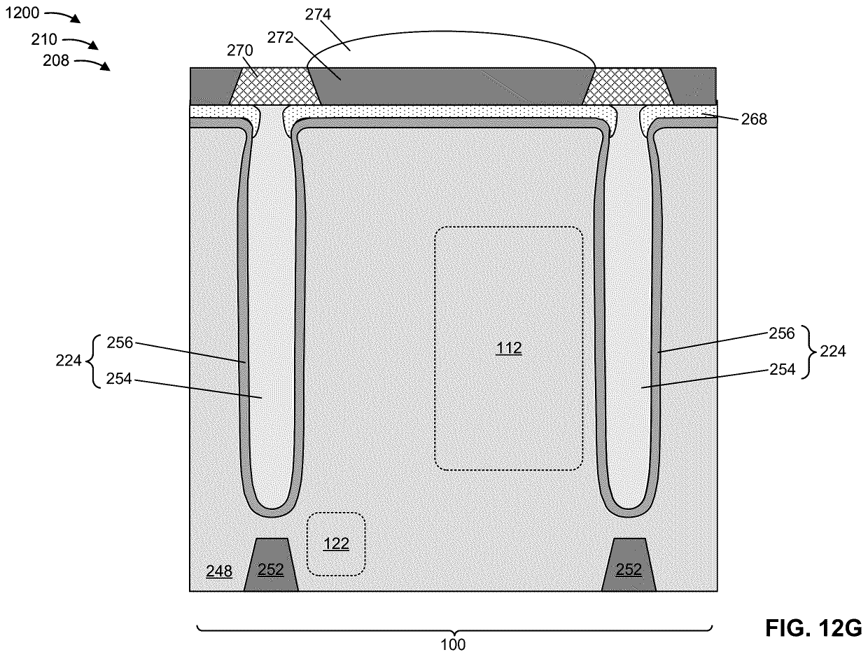

FIGS. 12A-12G are diagrams of an example implementation 1200 of forming a pixel sensor array 222 of a sensor device 208 (or a portion thereof) described herein. In particular, the example implementation 1200 may include an example of performing backside processing on a backside of the semiconductor layer 248 of the sensor device 208 to form a backside pixel sensor array 222 for the sensor device 208. In some implementations, one or more of the semiconductor processing operations described in connection with FIGS. 12A-12G may be performed using one or more semiconductor processing tools, such as a deposition tool, an exposure tool, a developer tool, an etch tool, a planarization tool, a plating tool, an ion implantation tool, an annealing tool, a plasma tool, a corona charging tool, and/or a wafer/die transport tool, among other examples.

As shown in FIGS. 12A-12G, the example implementation 1200 of forming a pixel sensor array 222 is similar to the example implementation 700 illustrated and described in connection with FIGS. 7A-7I. For example, the trenches 702 for the segments of the isolation structure 224 may be formed in the semiconductor layer 248, the liner layer 256 may be conformally deposited on the sidewalls and bottom surfaces of the trenches 702, a treatment operation may be performed for the high hydrogen concentration material of the liner layer 256 to negatively charge the material of the liner layer 256, the ARC layer 268 may be formed over the backside surface of the semiconductor layer 248, the trenches 702 may be filled in with the material of the fill layer 254 of the isolation structures 224, and the grid structure 270, the color filter regions 272, and the micro-lenses may be formed over the ARC layer 268.

However, in the example implementation 1200, the liner layer 258 is omitted from the isolation structures 224. The material of the liner layer 256 is instead deposited on the sidewalls and bottom surfaces of the trenches 702 such that the liner layer 256 is in contact with the semiconductor layer 248. Hydrogen from the material of the liner layer 256 may diffuse directly from the liner layer 256 into the semiconductor layer 248 (e.g., as opposed to diffusing through the liner layer 258) as a result of the treatment operation.

As indicated above, FIGS. 12A-12G are provided as an example. Other examples may differ from what is described with regard to FIGS. 12A-12G.

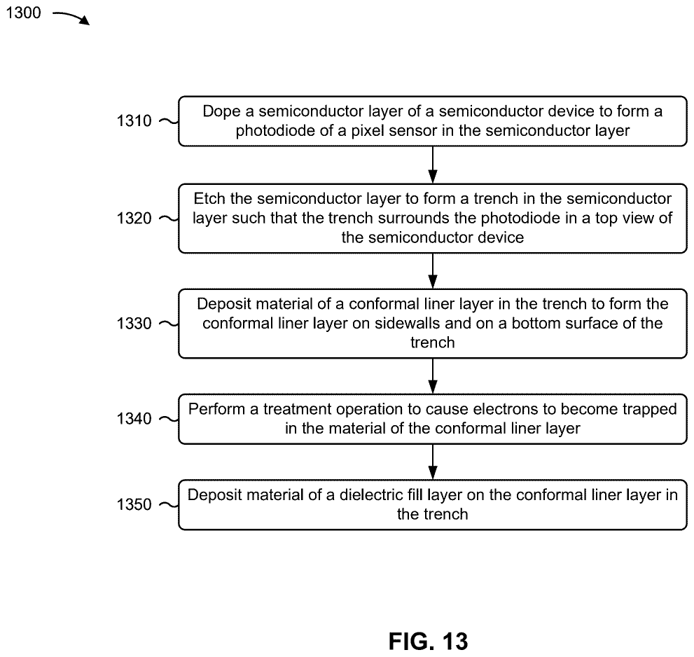

FIG. 13 is a flowchart of an example process 1300 associated with forming a semiconductor device described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a bonding tool, an annealing tool, a corona charging tool, a wafer/die transport tool, and/or another type of semiconductor processing tool.

As shown in FIG. 13, process 1300 may include doping a semiconductor layer of a semiconductor device to form a photodiode of a pixel sensor in the semiconductor layer (block 1310). For example, one or more semiconductor processing tools may be used to dope a semiconductor layer (e.g., a semiconductor layer 248) of a semiconductor device (e.g., a sensor device 208) to form a photodiode (e.g., a photodiode 112) of a pixel sensor (e.g., a pixel sensor 100) in the semiconductor layer, as described herein.

As further shown in FIG. 13, process 1300 may include etching the semiconductor layer to form a trench in the semiconductor layer such that the trench surrounds the photodiode in a top view of the semiconductor device (block 1320). For example, one or more semiconductor processing tools may be used to etch the semiconductor layer to form a trench (e.g., a trench 702) in the semiconductor layer such that the trench surrounds the photodiode in a top view of the semiconductor device, as described herein.

As further shown in FIG. 13, process 1300 may include depositing material of a conformal liner layer in the trench to form the conformal liner layer on sidewalls and on a bottom surface of the trench (block 1330). For example, one or more semiconductor processing tools may be used to deposit material of a conformal liner layer (e.g., a liner layer 258) in the trench to form the conformal liner layer on sidewalls and on a bottom surface of the trench, as described herein.

As further shown in FIG. 13, process 1300 may include performing a treatment operation to cause electrons to become trapped in the material of the conformal liner layer (block 1340). For example, one or more semiconductor processing tools may be used to perform a treatment operation to cause electrons (e.g., electrons 704) to become trapped in the material of the conformal liner layer, as described herein.

As further shown in FIG. 13, process 1300 may include depositing material of a dielectric fill layer on the conformal liner layer in the trench (block 1350). For example, one or more semiconductor processing tools may be used to deposit material of a dielectric fill layer (e.g., a fill layer 254) on the conformal liner layer in the trench, as described herein. In some implementations, the conformal liner layer and the dielectric fill layer in the trench correspond to a DTI structure (e.g., an isolation structure 224) that laterally surrounds the photodiode in the top view of the semiconductor device.

Process 1300 may include additional implementations, such as any single implementation or any combination of implementations described below and/or in connection with one or more other processes described elsewhere herein.

In a first implementation, the treatment operation includes an RTA operation.

In a second implementation, alone or in combination with the first implementation, performing the treatment operation includes performing the RTA operation at a temperature that is included in a range of approximately 400 degrees Celsius to approximately 900 degrees Celsius.

In a third implementation, alone or in combination with one or more of the first and second implementations, the treatment operation includes a corona charging operation.

In a fourth implementation, alone or in combination with one or more of the first through third implementations, performing the treatment operation includes performing the corona charging operation using a plasma (e.g., a plasma 1020), wherein a filter (e.g., a filter 1032) is used to filter protons and neutrons in the plasma so that the electrons are injected into the material of the conformal liner layer.

In a fifth implementation, alone or in combination with one or more of the first through fourth implementations, performing the treatment operation includes breaking silicon-hydrogen (Si—H) bonds in the material of the conformal liner layer to cause the electrons to become trapped at bonding sites (e.g., bonding sites 804) previously occupied by hydrogen in the material of the conformal liner layer.

In a sixth implementation, alone or in combination with one or more of the first through fifth implementations, the material of the conformal liner layer includes at least one of a silicon nitride (SiₓN_{y}), or an aluminum oxide (AlₓO_{y}).

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

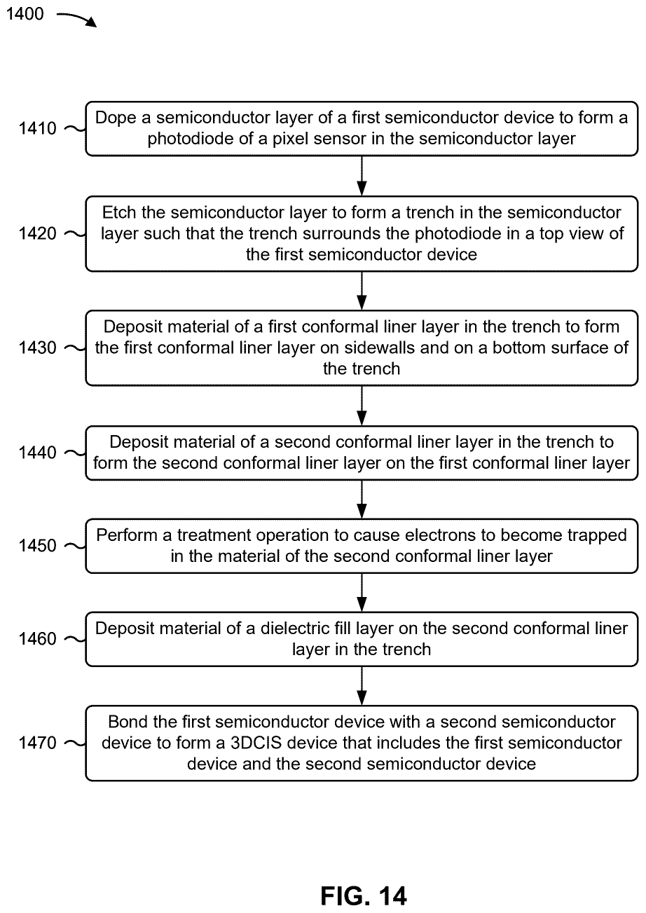

FIG. 14 is a flowchart of an example process 1400 associated with forming a semiconductor device described herein. In some implementations, one or more process blocks of

FIG. 14 are performed using one or more semiconductor processing tools, such as a deposition tool, an exposure tool, a developer tool, an etch tool, a planarization tool, an ion implantation tool, an annealing tool, a bonding tool, an annealing tool, a corona charging tool, a wafer/die transport tool, and/or another type of semiconductor processing tool.

As shown in FIG. 14, process 1400 may include doping a semiconductor layer of a first semiconductor device to form a photodiode of a pixel sensor in the semiconductor layer (block 1410). For example, one or more semiconductor processing tools may be used to dope a semiconductor layer (e.g., a semiconductor layer 248) of a first semiconductor device (e.g., a sensor device 208) to form a photodiode (e.g., a photodiode 112) of a pixel sensor (e.g., a pixel sensor 100) in the semiconductor layer, as described herein.

As further shown in FIG. 14, process 1400 may include etching the semiconductor layer to form a trench in the semiconductor layer such that the trench surrounds the photodiode in a top view of the first semiconductor device (block 1420). For example, one or more semiconductor processing tools may be used to etch the semiconductor layer to form a trench (e.g., a trench 702) in the semiconductor layer such that the trench surrounds the photodiode in a top view of the first semiconductor device, as described herein.

As further shown in FIG. 14, process 1400 may include depositing material of a first conformal liner layer in the trench to form the first conformal liner layer on sidewalls and on a bottom surface of the trench (block 1430). For example, one or more semiconductor processing tools may be used to deposit material of a first conformal liner layer (e.g., a liner layer 256) in the trench to form the first conformal liner layer on sidewalls and on a bottom surface of the trench, as described herein.

As further shown in FIG. 14, process 1400 may include depositing material of a second conformal liner layer in the trench to form the second conformal liner layer on the first conformal liner layer (block 1440). For example, one or more semiconductor processing tools may be used to deposit material of a second conformal liner layer (e.g., a liner layer 258) in the trench to form the second conformal liner layer on the first conformal liner layer, as described herein. In some implementations, an as-deposited hydrogen concentration of the material of the second conformal liner layer is greater than an as-deposited hydrogen concentration of the material of the first conformal liner layer.

As further shown in FIG. 14, process 1400 may include performing a treatment operation to cause electrons to become trapped in the material of the second conformal liner layer (block 1450). For example, one or more semiconductor processing tools may be used to perform a treatment operation to cause electrons to become trapped in the material of the second conformal liner layer, as described herein.

As further shown in FIG. 14, process 1400 may include depositing material of a dielectric fill layer on the second conformal liner layer in the trench (block 1460). For example, one or more semiconductor processing tools may be used to deposit material of a dielectric fill layer (e.g., a fill layer 254) on the second conformal liner layer in the trench, as described herein. In some implementations, the first conformal liner layer, the second conformal liner layer, and the dielectric fill layer in the trench correspond to a DTI structure (e.g., an isolation structure 224) that laterally surrounds the photodiode in the top view of the first semiconductor device.

As further shown in FIG. 14, process 1400 may include bonding the first semiconductor device with a second semiconductor device to form a 3DCIS device that includes the first semiconductor device and the second semiconductor device (block 1470). For example, one or more semiconductor processing tools may be used to bond the first semiconductor device with a second semiconductor device (e.g., a processing device 206) to form a 3DCIS device (e.g., an image sensor device 210) that includes the first semiconductor device and the second semiconductor device, as described herein.

Process 1400 may include additional implementations, such as any single implementation or any combination of implementations described below and/or in connection with one or more other processes described elsewhere herein.

In a first implementation, a hydrogen concentration of the material of the first conformal liner layer after the treatment operation is greater than the as-deposited hydrogen concentration of the material of the first conformal liner layer.

In a second implementation, alone or in combination with the first implementation, the material of the second conformal liner layer is positively charged prior to the treatment operation, and the treatment operation causes the material of the second conformal liner layer to become negatively charged.

In a third implementation, alone or in combination with one or more of the first and second implementations, etching the semiconductor layer to form the trench includes etching a back side of the semiconductor layer to form the trench after bonding the first semiconductor device with the second semiconductor device, and performing the treatment operation includes performing the treatment operation after bonding the first semiconductor device with the second semiconductor device.

In a fourth implementation, alone or in combination with one or more of the first through third implementations, etching the semiconductor layer to form the trench includes etching a font side of the semiconductor layer to form the trench prior to bonding the first semiconductor device with the second semiconductor device, and performing the treatment operation includes performing the treatment operation prior to bonding the first semiconductor device with the second semiconductor device.

In a fifth implementation, alone or in combination with one or more of the first through fourth implementations, performing the treatment operation includes breaking silicon-hydrogen (Si—H) bonds in the material of the second conformal liner layer to cause the electrons to become trapped at bonding sites (e.g., bonding sites 804) previously occupied by hydrogen in the material of the second conformal liner layer.

In a sixth implementation, alone or in combination with one or more of the first through fifth implementations, the material of the second conformal liner layer includes at least one of hydrogen-doped silicon nitride (Si₃N₄), or hydrogen-doped aluminum oxide (Al₂O₃).

In a seventh implementation, alone or in combination with one or more of the first through sixth implementations, process 1400 includes forming an ARC layer (e.g., an ARC layer 268) on the second conformal liner layer after performing the treatment operation.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, an isolation structure in a pixel sensor array of an image sensor device is manufactured to include a liner that passivates the dangling bonds in a substrate layer of the image sensor that were formed during etching of the substrate layer to form the trenches in which the segments of the isolation structure were formed. As described herein, a liner may be formed as a passivation layer in a recess in which an isolation structure is to be formed. The material of the liner includes a high concentration of hydrogen (H). The high hydrogen concentration may be achieved through in-situ doping and/or by another technique. The hydrogen in the material of the liner bonds to silicon (Si) in the material of the liner to form silicon-hydrogen (Si—H) bonds. A post-deposition treatment operation may be performed to break the silicon-hydrogen bonds in the material of the liner layer to cause the hydrogen to migrate to the dangling bonds in the substrate layer, which passivates the dangling bonds. Electrons replace the hydrogen in the material of the liner, becoming trapped at bonding sites previously occupied by the hydrogen in the material of the liner. This results in the material of the liner having a net electronegativity. The electronegativity of the material of the liner, and/or the passivation of the dangling bonds of the substrate layer, reduces the likelihood of and/or the amount of charge buildup around the isolation structure, which increases the sensitivity of the pixel sensors of the pixel sensor array. The increased sensitivity of the pixel sensors may increase the responsiveness of the pixel sensors (which may increase low-light performance) and/or may increase the dynamic range of the pixel sensors, among other examples.

As described in greater detail above, some implementations described herein provide a method. The method includes doping a semiconductor layer of a semiconductor device to form a photodiode of a pixel sensor in the semiconductor layer. The method includes etching the semiconductor layer to form a trench in the semiconductor layer such that the trench surrounds the photodiode in a top view of the semiconductor device. The method includes depositing material of a conformal liner layer in the trench to form the conformal liner layer on sidewalls and on a bottom surface of the trench. The method includes performing a treatment operation to cause electrons to become trapped in the material of the conformal liner layer. The method includes depositing material of a dielectric fill layer on the conformal liner layer in the trench, where the conformal liner layer and the dielectric fill layer in the trench correspond to a DTI structure that laterally surrounds the photodiode in the top view of the semiconductor device.

As described in greater detail above, some implementations described herein provide a method. The method includes doping a semiconductor layer of a first semiconductor device to form a photodiode of a pixel sensor in the semiconductor layer. The method includes etching the semiconductor layer to form a trench in the semiconductor layer such that the trench surrounds the photodiode in a top view of the first semiconductor device. The method includes depositing material of a first conformal liner layer in the trench to form the first conformal liner layer on sidewalls and on a bottom surface of the trench. The method includes depositing material of a second conformal liner layer in the trench to form the second conformal liner layer on the first conformal liner layer, where an as-deposited hydrogen concentration of the material of the second conformal liner layer is greater than an as-deposited hydrogen concentration of the material of the first conformal liner layer. The method includes performing a treatment operation to cause electrons to become trapped in the material of the second conformal liner layer. The method includes depositing material of a dielectric fill layer on the second conformal liner layer in the trench, where the first conformal liner layer, the second conformal liner layer, and the dielectric fill layer in the trench correspond to a DTI structure that laterally surrounds the photodiode in the top view of the first semiconductor device. The method includes bonding the first semiconductor device with a second semiconductor device to form a 3DCIS device that includes the first semiconductor device and the second semiconductor device.

As described in greater detail above, some implementations described herein provide an image sensor device. The image sensor device includes a sensor device. The image sensor device includes a processing device bonded to the sensor device such that the sensor device and the processing device are stacked in the image sensor device. A first side of the sensor device is bonded to the processing device. The sensor device includes a plurality of photodiodes in a semiconductor layer of the sensor device and an isolation structure. The isolation structure includes a plurality of interconnected segments in the semiconductor layer that extend laterally around the plurality of photodiodes. In a top view of the isolation structure, the isolation structure includes rounded corners at locations where the plurality of interconnected segments intersect. The plurality of interconnected segments of the isolation structure include a dielectric fill layer and a liner between the semiconductor layer and the dielectric fill layer. A hydrogen concentration in the liner is greater than a hydrogen concentration in the dielectric fill layer. The hydrogen concentration in the liner is greater than a hydrogen concentration in a portion of the semiconductor layer around the isolation structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
doping a semiconductor layer of a semiconductor device to form a photodiode of a pixel sensor in the semiconductor layer;
etching the semiconductor layer to form a trench in the semiconductor layer such that the trench surrounds the photodiode in a top view of the semiconductor device;
depositing material of a conformal liner layer in the trench to form the conformal liner layer on sidewalls and on a bottom surface of the trench,
performing a treatment operation to cause electrons to become trapped in the material of the conformal liner layer; and
depositing material of a dielectric fill layer on the conformal liner layer in the trench,
wherein the conformal liner layer and the dielectric fill layer in the trench correspond to a deep trench isolation (DTI) structure that laterally surrounds the photodiode in the top view of the semiconductor device.

2. The method of claim 1, wherein the treatment operation comprises a rapid thermal anneal (RTA) operation.

3. The method of claim 2, wherein performing the treatment operation comprises:
performing the RTA operation at a temperature that is included in a range of approximately 400 degrees Celsius to approximately 900 degrees Celsius.

4. The method of claim 1, wherein the treatment operation comprises a corona charging operation.

5. The method of claim 4, wherein performing the treatment operation comprises: performing the corona charging operation using a plasma,
wherein a filter is used to filter protons and neutrons in the plasma so that the electrons are injected into the material of the conformal liner layer.

6. The method of claim 1, wherein performing the treatment operation comprises:
breaking silicon-hydrogen (Si—H) bonds in the material of the conformal liner layer to cause the electrons to become trapped at bonding sites previously occupied by hydrogen in the material of the conformal liner layer.

7. The method of claim 1, wherein the material of the conformal liner layer comprises at least one of:
a silicon nitride (SiₓN_{y}), or
an aluminum oxide (AlₓO_{y}).

8. A method, comprising:
doping a semiconductor layer of a first semiconductor device to form a photodiode of a pixel sensor in the semiconductor layer;
etching the semiconductor layer to form a trench in the semiconductor layer such that the trench surrounds the photodiode in a top view of the first semiconductor device;
depositing material of a first conformal liner layer in the trench to form the first conformal liner layer on sidewalls and on a bottom surface of the trench;
depositing material of a second conformal liner layer in the trench to form the second conformal liner layer on the first conformal liner layer,
wherein an as-deposited hydrogen concentration of the material of the second conformal liner layer is greater than an as-deposited hydrogen concentration of the material of the first conformal liner layer;
performing a treatment operation to cause electrons to become trapped in the material of the second conformal liner layer;
depositing material of a dielectric fill layer on the second conformal liner layer in the trench,
wherein the first conformal liner layer, the second conformal liner layer, and the dielectric fill layer in the trench correspond to a deep trench isolation (DTI) structure that laterally surrounds the photodiode in the top view of the first semiconductor device; and
bonding the first semiconductor device with a second semiconductor device to form a three-dimensional complementary metal-oxide-semiconductor (CMOS) image sensor (3DCIS) device that includes the first semiconductor device and the second semiconductor device.

9. The method of claim 8, wherein a hydrogen concentration of the material of the first conformal liner layer after the treatment operation is greater than the as-deposited hydrogen concentration of the material of the first conformal liner layer.

10. The method of claim 8, wherein the material of the second conformal liner layer is positively charged prior to the treatment operation; and
wherein the treatment operation causes the material of the second conformal liner layer to become negatively charged.

11. The method of claim 8, wherein etching the semiconductor layer to form the trench comprises:
etching a back side of the semiconductor layer to form the trench after bonding the first semiconductor device with the second semiconductor device,
wherein performing the treatment operation comprises:
performing the treatment operation after bonding the first semiconductor device with the second semiconductor device.

12. The method of claim 8, wherein etching the semiconductor layer to form the trench comprises:
etching a font side of the semiconductor layer to form the trench prior to bonding the first semiconductor device with the second semiconductor device,
wherein performing the treatment operation comprises:
performing the treatment operation prior to bonding the first semiconductor device with the second semiconductor device.

13. The method of claim 8, wherein performing the treatment operation comprises:
breaking silicon-hydrogen (Si—H) bonds in the material of the second conformal liner layer to cause the electrons to become trapped at bonding sites previously occupied by hydrogen in the material of the second conformal liner layer.

14. The method of claim 8, wherein the material of the second conformal liner layer comprises at least one of:
hydrogen-doped silicon nitride (Si₃N₄), or
hydrogen-doped aluminum oxide (Al₂O₃).

15. The method of claim 8, further comprising:
forming an antireflective coating (ARC) layer on the second conformal liner layer after performing the treatment operation.

16. An image sensor device, comprising:
a sensor device; and
a processing device bonded to the sensor device such that the sensor device and the processing device are stacked in the image sensor device,
wherein a first side of the sensor device is bonded to the processing device, and
wherein the sensor device comprises:
a plurality of photodiodes in a semiconductor layer of the sensor device;
an isolation structure comprising a plurality of interconnected segments in the semiconductor layer that extend laterally around the plurality of photodiodes,
wherein, in a top view of the isolation structure, the isolation structure comprises rounded corners at locations where the plurality of interconnected segments intersect, and
wherein the plurality of interconnected segments of the isolation structure comprise:
a dielectric fill layer; and
a liner between the semiconductor layer and the dielectric fill layer,
wherein a hydrogen concentration in the liner is greater than a hydrogen concentration in the dielectric fill layer, and
wherein the hydrogen concentration in the liner is greater than a hydrogen concentration in a portion of the semiconductor layer around the isolation structure.

17. The semiconductor of claim 16, wherein the plurality of interconnected segments of the isolation structure further comprise:
another liner between the liner and the semiconductor layer,
wherein a material of the liner and a material of the other liner are different materials.

18. The semiconductor of claim 17, wherein a band gap of the material of the liner is less than a band gap of the material of the other liner.

19. The semiconductor of claim 17, wherein the hydrogen concentration in the liner is greater than a hydrogen concentration in the material of the other liner.

20. The semiconductor of claim 17, wherein the material of the liner comprises a nitride; and
wherein the material of the other liner comprises an oxide.
